(19) United States
(12) Patent Application Publication
(10) Pub. No.: US 2025/0351690 A1
(43) Pub. Date: Nov. 13, 2025

(54) LIGHT EMITTING DISPLAY DEVICE

(71) Applicant: Samsung Display Co., LTD., Yongin-si (KR)

(72) Inventors: Sung Jae MOON, Yongin-si (KR); Dong-Hyeon KI, Yongin-si (KR); Kang Moon JO, Yongin-si (KR)

(73) Assignee: Samsung Display Co., LTD., Yongin-si (KR)

(21) Appl. No.: 18/987,931

(22) Filed: Dec. 19, 2024

(30) Foreign Application Priority Data
May 7, 2024 (KR) 10-2024-0060017

(51) Int. Cl. H10K 59/131

(52) U.S. Cl. CPC H10K 59/131

(57) ABSTRACT

Provided is a light emitting display device including a substrate, a voltage line positioned on the substrate and transmitting a constant voltage, a passivation layer positioned on the voltage line, a via layer positioned on the passivation layer, a connection electrode positioned on the via layer, a pixel defining layer positioned on the connection electrode, and a cathode electrode positioned on the pixel defining layer.

### CROSS-REFERENCE TO RELATED APPLICATION

This application claims priority to and the benefit of Korean Patent Application No. 10-2024-0060017 under 35 U.S.C. § 119, filed on May 7, 2024, in the Korean Intellectual Property Office, the entire contents of which are incorporated herein by reference.

### BACKGROUND

### 1. Technical Field

The disclosure relates to a light emitting display device, and more specifically, to a light emitting display device applying a laser drilling method.

### 2. Description of the Related Art

A display device is a device that displays a screen and includes a liquid crystal display (LCD) and an organic light emitting diode (OLED). Display devices are used in various electronic devices such as mobile phones, navigation devices, digital cameras, electronic books, portable game consoles, and various terminals.

Organic light emitting display devices have self-luminance characteristics and, unlike liquid crystal displays, do not require a separate light source, so thickness and weight may be reduced. Additionally, organic light emitting display devices have high-quality characteristics such as low power consumption, high luminance, and fast response speed.

### SUMMARY

Embodiments provide a light emitting display device capable of laser drilling that transmits voltage using a laser.

Embodiments provide a high-resolution light emitting display device that may confirm whether laser drilling has been properly formed.

According to embodiments, a light emitting display device includes a substrate, a voltage line positioned on the substrate and transmitting a constant voltage, a passivation layer positioned on the voltage line, a via layer positioned on the passivation layer, a connection electrode positioned on the via layer, a pixel defining layer positioned on the connection electrode, and a cathode electrode positioned on the pixel defining layer, wherein the pixel defining layer has a first opening that overlaps the connection electrode in a plan view, the via layer has a second opening that overlaps the connection electrode in a plan view, the passivation layer has a third opening that overlaps the connection electrode in a plan view, the cathode electrode and the connection electrode are electrically connected to each other through the first opening of the pixel defining layer, the voltage line and the connection electrode are electrically connected to each other through the second opening of the via layer and the third opening of the passivation layer, and at least a portion of the third opening of the passivation layer does not overlap the second opening of the via layer in a plan view.

The second opening of the via layer and the third opening of the passivation layer may be positioned in the first opening of the pixel defining layer in a plan view.

The third opening of the passivation layer and the second opening of the via layer may have a planar shape in a plan view.

The third opening of the passivation layer and the second opening of the via layer may have a triangular, rectangular, hexagonal, octagonal, or polygonal planar shape, or a planar shape with a polygonal shape cut out.

The direction in which a long side of the second opening of the via layer extends may be different from the direction in which an upper side of the third opening of the passivation layer extends.

The direction in which a long side of the second opening of the via layer extends may be perpendicular to the direction in which the upper side of the third opening of the passivation layer extends.

The second opening of the via layer may be positioned in the third opening of the passivation layer in a plan view.

The third opening of the passivation layer may be flush with the first opening of the pixel defining layer in a plan view.

A low driving voltage may be applied to the voltage line which is electrically connected a light emitting display device.

An anode electrode positioned on the via layer may be further included, and the pixel defining layer further includes a fourth opening that overlaps the anode electrode in a plan view, and the anode electrode and the connection electrode may be formed of a same material.

It may further include an intermediate layer positioned on the anode electrode and the pixel defining layer, wherein the intermediate layer is opened by laser drilling at a portion overlapping the connection electrode to electrically connect the cathode electrode and the connection electrode.

A light emitting display device according to an embodiment includes a substrate, a voltage line positioned on the substrate and transmitting a constant voltage, a via layer positioned on the voltage line; a connection electrode positioned on the via layer, a pixel defining layer positioned on the connection electrode, and a cathode electrode positioned on the pixel defining layer, wherein the pixel defining layer has a first opening that overlaps the connection electrode in a plan view, and the via layer has a second opening that overlaps the connection electrode in a plan view, the cathode electrode and the connection electrode are electrically connected to each other through the first opening of the pixel defining layer, the voltage line and the connection electrode are electrically connected to each other through the second opening of the via layer, and at least a portion of the second opening of the via layer does not overlap the first opening of the pixel defining layer in a plan view.

The above includes the passivation layer positioned between the voltage line and the via layer, and the passivation layer has a third opening that overlaps the connection electrode in a plan view, and at least part of the third opening of the passivation layer may not overlap the first opening of the pixel defining layer.

The second opening of the via layer may be positioned in the third opening of the passivation layer in a plan view.

It may further include an anode electrode positioned on the via layer, and the pixel defining layer may further include an opening that overlaps the anode electrode in a plan view, and the anode electrode and the connection electrode may be formed of a same material.

It may further include an intermediate layer positioned on the anode electrode and the pixel defining layer, wherein the intermediate layer is opened by laser drilling at a portion overlapping the connection electrode to electrically connect the cathode electrode and the connection electrode.

The light emitting display device according to an embodiment includes a substrate, a voltage line positioned on the substrate and transmitting a constant voltage, a via layer positioned on the voltage line, a connection electrode positioned on the via layer, a pixel defining layer positioned on the connection electrode, and a cathode electrode positioned on the pixel defining layer, the pixel defining layer has a first opening that overlaps the connection electrode in a plan view, the via layer has a second opening that overlaps the connection electrode in a plan view, the cathode electrode and the connection electrode are electrically connected to each other through the first opening of the pixel defining layer, and the voltage line and the connection electrode are electrically connected to each other through the second opening of the via layer, and the second opening of the via layer has a planar shape in a plan view.

The second opening of the via layer may have a triangular, rectangular, hexagonal, octagonal, or polygonal planar shape, or a planar shape with a polygonal shape cut out.

It may further include an anode electrode positioned on the via layer, and the pixel defining layer may further include an opening that overlaps the anode electrode in a plan view, and the anode electrode and the connection electrode may be formed of a same material.

It may further include an intermediate layer positioned on the anode electrode and the pixel defining layer, wherein the intermediate layer is opened by laser drilling at a portion overlapping the connection electrode to electrically connect the cathode electrode to the connection electrode.

According to the embodiments, by forming the position of the processing hole, which is formed by laser drilling, to at least partially overlap the opening that electrically connects the connection electrode and the voltage line, the space required for laser drilling may be reduced, enabling laser drilling in high-resolution light emitting display devices.

According to the embodiments, by forming or positioning the openings that electrically connect the connection electrodes and the voltage lines differently from the shape of the processed holes formed by laser drilling, or distinguishing their positions from each other, it is possible to secure space for laser drilling even in high-resolution light emitting display devices and to ensure that the laser drilling is properly formed.

According to the embodiments, when electrically connecting the connection electrode and the voltage line, by forming the opening of the via layer with a narrower width than the opening of the passivation layer at least in part, it is possible to prevent the cathode electrode from being disconnected due to the steep boundary of the passivation layer's opening, ensuring that the driving low-voltage may be transmitted to the cathode electrode without problems.

### BRIEF DESCRIPTION OF THE DRAWINGS

FIG. 1 is a schematic plan view showing the structure of a laser drilling area in a light emitting display device according to an embodiment.

FIGS. 2 and 3 are schematic cross-sectional views taken along lines II-II′ and

III-III′ of FIG. 1.

FIG. 4 is a schematic photograph of a cross-section of a portion of a light emitting display device.

FIG. 5 is a schematic plan view after laser drilling in FIG. 1.

FIGS. 6 and 7 are schematic cross-sectional views taken along lines VI-VI′ and VII-VII′ of FIG. 5.

FIG. 8 is a schematic flow chart illustrating a method for determining whether there is an error in laser drilling according to an embodiment.

FIG. 9 is a schematic diagram illustrating each center in one embodiment.

FIG. 10 is a schematic table summarizing various embodiments and their characteristics.

FIG. 11 is a schematic plan view showing the structure of a laser drilling area according to a comparative example.

FIG. 12 is a schematic cross-sectional view of the comparative example of FIG. 11.

FIG. 13 is a photograph taken after laser drilling was performed in the comparative example of FIG. 11.

FIG. 14 is a schematic table summarizing various comparative examples and their characteristics.

FIG. 15 is a schematic plan view showing the structure of a laser drilling area according to another comparative example.

FIGS. 16 and 17 are schematic plan views showing the structure of a laser drilling area according to another embodiment.

FIG. 18 is a table schematically illustrating steps for manufacturing some layers of a light emitting display device according to an embodiment.

FIG. 19 is a schematic cross-sectional view of a light emitting display device according to an embodiment.

FIG. 20 is a schematic diagram of an equivalent circuit of a pixel of a light emitting display device according to an embodiment.

FIG. 21 is a table schematically illustrating steps for manufacturing some layers of a light emitting display device according to another embodiment.

### DETAILED DESCRIPTION OF THE EMBODIMENTS

Hereinafter, with reference to the attached drawings, various embodiments of the disclosure will be described in detail so that those skilled in the art may easily implement the disclosure. The invention may be implemented in many different forms and is not limited to the embodiments described herein.

In order to clearly explain the disclosure, parts that are not relevant to the description are omitted, and identical or similar components are assigned the same reference numerals throughout the specification.

In addition, the size and thickness of each component shown in the drawings are arbitrarily shown for convenience of explanation, so the disclosure is not necessarily limited to that which is shown. In the drawing, the thickness is enlarged to clearly express various layers and areas. And in the drawings, for convenience of explanation, the thicknesses of some layers and regions are exaggerated.

Additionally, when a part, such as a layer, membrane, region, plate, or component is said to be “above” or “on” another part, this means not only when it is “directly above” another part, but also when there is another part in between. In contrast, when an element is referred to as being “directly on” another element, there are no intervening elements present. In addition, being “above” or “on” a reference part means being positioned above or below the reference part, and does not necessarily mean being positioned “above” or “on” it in the direction opposite to gravity.

In addition, throughout the specification, when a part is said to “include” a certain element, this means that it may further include other elements, rather than excluding other elements, unless specifically stated to the contrary.

In addition, throughout the specification, when reference is made to “in a plan view,” this means when the target part is viewed from above, and when reference is made to “in cross-section,” this means when a cross-section of the target portion is cut vertically and viewed from the side.

In addition, throughout the specification, when “connected” is used, this does not mean only when two or more components are directly connected, but when two or more components are indirectly connected through other components, they are physically connected, including not only the case of being connected or electrically connected, but also the case where all parts, which are referred to by different names depending on location or function, are substantially connected to each other.

In addition, throughout the specification, when a portion such as a wiring, layer, film, region, plate, or component is said to “extend in the first or second direction,” this means not only a straight shape extending in that direction, but also includes a structure that extends overall along the first or second direction, and also includes a structure that is bent at some part, has a zigzag structure, or extends while including a curved structure.

In addition, electronic devices (e.g., mobile phones, TVs, monitors, laptop computers, etc.) containing display devices, display panels, etc. described in the specification, or display devices, display panels, etc. manufactured by the manufacturing method described in the specification are not excluded from the scope of rights of this specification.

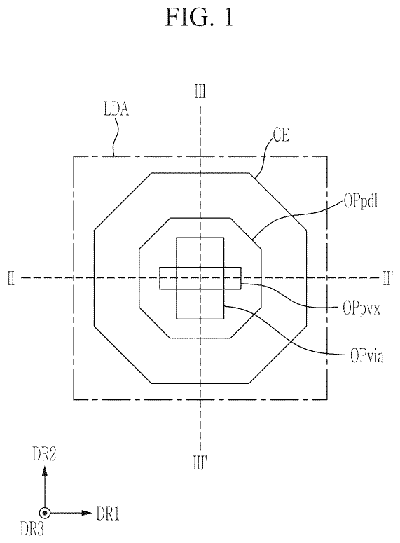

In the following, the drawings will be described with particular reference to the structure of the laser drilling area that may be positioned in part of the display area of the light emitting display device, and will first be described with reference to FIG. 1 which shows a schematic planar structure.

FIG. 1 is a schematic plan view showing the structure of a laser drilling area in a light emitting display device according to an embodiment.

In FIG. 1, a connection electrode CE positioned in a laser drilling area LDA and openings OPpvx, OPvia, and OPpdl positioned above and below the connection electrode CE are shown, respectively.

A voltage (e.g., driving low-voltage ELVSS) to be transmitted to a cathode electrode of the light emitting diode may be applied through laser drilling. The connection electrode CE may be formed in the same layer as an anode electrode included in the light emitting diode (also referred to as the anode layer), and may be formed from the same material as the anode electrode, and if the anode electrode is formed from multiple layers, the connection electrode CE may also be formed from multiple layers. The anode electrode layer including the connection electrode CE and the anode electrode may be made of a single layer including a transparent conductive oxide layer or a metal material, or a multiple layer including these. For example, transparent conductive oxide layers may include ITO (indium tin oxide), poly-ITO, IZO (indium zinc oxide), IGZO (indium gallium zinc oxide), and ITZO (indium tin zinc oxide), and the metal materials may include silver (Ag), molybdenum (Mo), copper (Cu), gold (Au), and aluminum (Al).

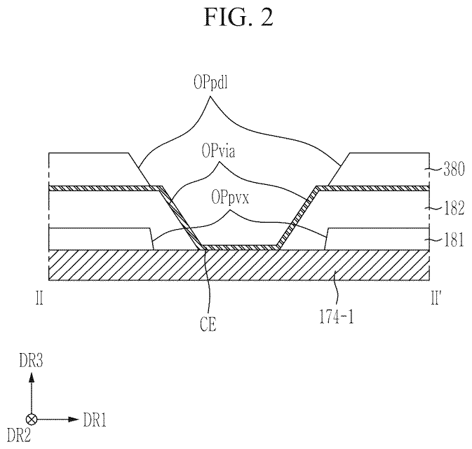

A pixel defining layer (see 380 in FIG. 2) may be positioned on top of the connection electrode CE, and in the pixel defining layer, there may be a first opening (OPpdl) that exposes at least a part of the connection electrode CE for laser drilling. The first opening OPpdl of the pixel defining layer 380 may overlap the connection electrode CE in a plan view. The pixel defining layer 380 may include one of photoresist, polyacrylic resin, polyimide resin, and acrylic resin, and these resins may be used alone or in combination with each other. In other embodiments, the pixel defining layer 380 may have transparent characteristics so that light may transmit, or it may contain a black organic material or light blocking material, be black, and have characteristics of absorbing/blocking light.

A power line (not shown) connected to the connection electrode CE may be positioned below the connection electrode CE, and the connection electrode CE and the power line may be connected through openings OPvia, OPpdl. The voltage applied to the power line may be transmitted to the connection electrode CE, and through laser drilling, the cathode electrode and the connection electrode CE may be electrically connected and transmitted to the cathode electrode.

In an embodiment of the light emitting display device, a via layer (see 182 in FIG. 2) and a passivation layer (see 181 in FIG. 2) may be positioned between the connection electrode CE and the power line, with the second opening OPvia situated in the via layer 182, and the third opening OPpvx situated in the passivation layer. The second opening OPvia of the via layer 182 and the third opening OPpvx of the passivation layer overlap the connection electrode CE in a plan view. The second opening OPvia of the via layer 182 and the third opening OPpvx of the passivation layer may be positioned in the first opening OPpdl of the pixel defining layer 380 in a plan view. For example, the via layer 182 may be formed of an organic insulating layer and may include one or more materials selected from the group consisting of photoresist, polyacrylic resin, polyimide resin, acrylic resin, benzocyclobutene, and phenol resin. Meanwhile, the passivation layer may be formed of an inorganic insulating layer and may include one of silicon oxide SiOₓ, silicon nitride SiNₓ, and silicon oxynitride SiONₓ, or may be formed as a multiple-layer structure using these. The passivation layer may have a thicker inorganic insulating layer structure than other inorganic insulating layers.

In FIG. 1, the third opening OPpvx of the passivation layer and the second opening OPvia of the via layer 182 may be formed to overlap in a plan view with the first opening OPpdl of the pixel defining layer 380, which connects the connection electrode CE to the cathode electrode above, thus allowing the connection electrode CE to be electrically connected to the power line below, thereby reducing the area occupied by the laser drilling area LDA that includes this configuration. As a result, the laser drilling area LDA may be formed even in high-resolution light emitting display devices.

In FIG. 1, the third opening OPpvx of the passivation layer and/or the second opening OPvia of the via layer 182 has a rectangular shape rather than a circular shape, and may be elongated on one side rather than being a square. In other embodiments, the third opening OPpvx of the passivation layer and/or the second opening OPvia of the via layer 182 may have various polygonal planar shapes such as triangles, rectangles, hexagons, octagons, etc., or a planar shape with the polygonal shape cut off. The direction in which the long sides of the planar shapes of the third opening OPpvx of the passivation layer and the second opening OPvia of the via layer 182 extend may be different from each other, and in other embodiments, they may be perpendicular. For example, the long side may be the longest side among the sides of the corresponding plane shape.

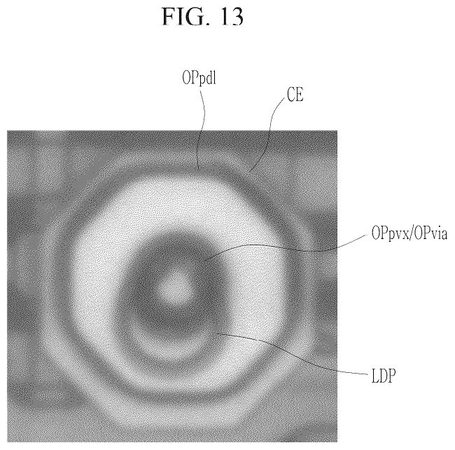

In case that laser drilling is performed, the machined holes formed by the laser drilling may be circular in shape (see LDP in FIG. 13), therefore, by forming holes in shapes different from that of the laser drilling holes (for example, square, triangle, and various other shapes), it is possible to clearly identify the positions of the laser drilling and confirm whether the laser drilling has been performed properly, and prevent any problems caused by the laser drilling.

In FIG. 1, the third opening OPpvx of the passivation layer may not overlap at all with the second opening OPvia of the via layer 182, and at least part of the third opening OPpvx of the passivation layer may have a structure that does not overlap the second opening OPvia of the via layer 182. The passivation layer may have a steep boundary slope, and the conductive layer positioned above it may be disconnected, so at least part of the boundary of the third opening OPpvx of the passivation layer may be covered with a via layer 182 to prevent the conductive layer above from breaking.

The voltage delivered to the cathode electrode through the connection electrode CE electrically connected by laser drilling may be either the driving voltage ELVDD or the driving low-voltage ELVSS, with the following discussion focusing on embodiments where the voltage delivered to the cathode electrode is the driving low-voltage ELVSS.

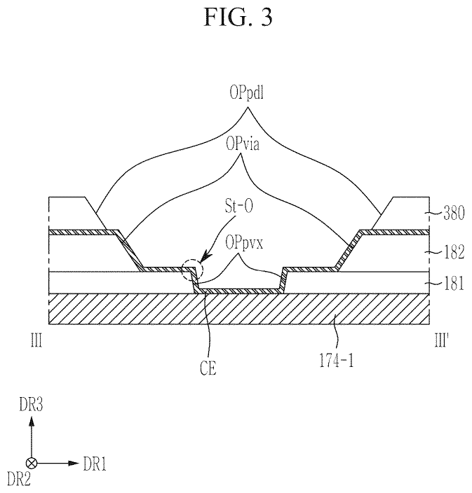

The cross-sectional structure cut along the II-II′ and III-III′ cross-section lines shown in FIG. 1 will be examined through FIGS. 2 and 3 below.

FIG. 1.

FIGS. 2 and 3 are cross-sectional views taken along lines II-II′ and III-III′ of FIG. 2 is a schematic cross-sectional view taken along cross-sectional line II-II′ of FIG. 1, and FIG. 3 is a schematic cross-sectional view taken along cross-sectional line III-III′.

FIG. 2 and FIG. 3 illustrate a structure in which the connection electrode CE and the auxiliary driving low-voltage line 174-1 are electrically connected, and the lower structure of the auxiliary driving low-voltage line 174-1 is omitted. The auxiliary driving low-voltage line 174-1 may be also referred to as a voltage line, and in other embodiments, a connection electrode CE that electrically connects to a voltage line to which a voltage other than the driving low-voltage ELVSS (for example, the driving voltage ELVDD) is applied may be electrically connected.

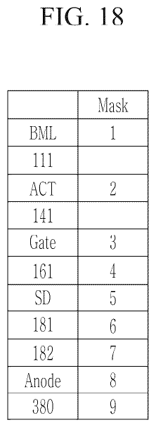

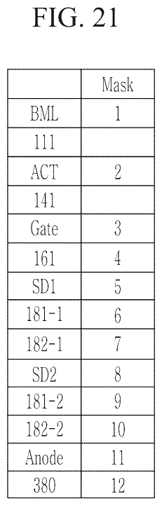

The auxiliary driving low-voltage line 174-1 may be a voltage line through which the driving low-voltage ELVSS is transmitted, and may be formed of the same material as one of the transistors or electrodes included in the pixel driver that provides current to the light emitting diode to display luminance. The transistor or electrode included in the pixel driver may include various semiconductor layers, conductive layers, and insulating layers, and the stacked structure of some embodiments will be described in FIG. 18 or FIG. 21. The auxiliary driving low-voltage line 174-1 may be formed as a data conductive layer (see SD in FIG. 18, SD1, SD2 in FIG. 21), and may include metals or metal alloys such as aluminum (Al), copper (Cu), molybdenum (Mo), titanium (Ti), etc., and may be made of a single layer or multiple layers.

Referring to FIGS. 2 and 3, the auxiliary driving low-voltage line 174-1 may be covered with a passivation layer 181, and a part of the auxiliary driving low-voltage line 174-1 may be exposed by the third opening OPpvx positioned in the passivation layer 181. For example, the passivation layer 181 may be formed of an inorganic insulating layer and may include one of silicon oxide SiOₓ, silicon nitride SiNₓ, and silicon oxynitride SiONₓ, or may be formed as a multiple-layer structure using these. The passivation layer 181 may have an inorganic insulating layer structure formed to be thicker than other inorganic insulating layers.

The passivation layer 181 may be covered by a via layer 182, and the via layer 182 may have a second opening OPvia that at least partially overlaps the third opening OPpvx of the passivation layer 181, the auxiliary driving low-voltage line 174-1 may have a structure in which a portion is exposed by the third opening OPpvx of the passivation layer 181 and the second opening OPvia of the via layer 182. The via layer 182 may be formed of an organic insulating layer and may include one or more materials selected from the group consisting of photoresist, polyacrylic resin, polyimide resin, acrylic resin, benzocyclobutene, and phenol resin.

Above the via layer 182 may be the connection electrode CE, which is electrically connected while directly contacting a part of the auxiliary low-voltage line 174-1 exposed by the third opening OPpvx of the passivation layer 181 and the second opening OPvia of the via layer 182. Like the anode electrode, the connection electrode CE may be made of a single layer containing a transparent conductive oxide layer or a metal material or a multiple-layer structure containing these. For example, the transparent conductive oxide may include ITO (indium tin oxide), poly-ITO, IZO (indium zinc oxide), IGZO (indium gallium zinc oxide), and ITZO (indium tin zinc oxide), and the metal material may include silver (Ag), molybdenum (Mo), copper (Cu), gold (Au), and aluminum (Al).

A pixel defining layer 380 may be covered on the connection electrode CE, and a first opening OPpdl may be formed in the pixel defining layer 380 to expose a portion of the connection electrode CE. The pixel defining layer 380 may include one of photoresist, polyacrylic resin, polyimide resin, and acrylic resin, and these resins may be used alone or in combination with each other. In other embodiments, the pixel defining layer 380 may have transparent properties, allowing light to pass through, or may contain a black organic material or light blocking material, may be black, and may have light absorbing/blocking properties.

FIGS. 2 and 3 show that the widths of the third opening OPpvx of the passivation layer 181 and the second opening OPvia of the via layer 182 differ depending on the position of the cross-section line, and accordingly, there may be a difference in the structure where the connection electrode CE and the auxiliary driving low-voltage line 174-1 are in contact. The via layer 182 may be formed with a gentle slope at the boundary of the second opening OPvia, and the passivation layer 181 may be formed with a steep slope at the boundary between the third opening OPpvx. As a result, whether the connection electrode CE is formed with a gentle slope or a sharp slope may vary depending on which opening boundary surface the connection electrode CE is formed along.

The connection structure of the connection electrode CE and the auxiliary driving low-voltage line 174-1 in the structure of FIG. 2 will be described.

Referring to FIG. 2, the width of the third opening OPpvx of the passivation layer 181 may be formed larger than the width of the second opening OPvia of the via layer 182 so that the boundary of the third opening OPpvx of the passivation layer 181 may be covered by the via layer 182. As a result, the connection electrode CE may have a structure in which it is electrically connected to the auxiliary driving low-voltage line 174-1 only through the second opening OPvia of the via layer 182.

The connection structure of the connection electrode CE and the auxiliary driving low-voltage line 174-1 in the structure of FIG. 3 will be examined.

Referring to FIG. 3, the width of the third opening OPpvx of the passivation layer 181 may be formed narrower than the width of the second opening OPvia of the via layer 182 so that the boundary of the third opening OPpvx of the passivation layer 181 may be exposed but not covered by the via layer 182. As a result, the connection electrode CE may have a structure that connects not only through the second opening OPvia of the via layer 182 but also through the third opening OPpvx of the passivation layer 181 with the auxiliary driving low-voltage line 174-1. For example, there may be a high possibility that the conductive layer formed thereon will be disconnected due to a sudden change in the angle of the upper edge St-O of the third opening OPpvx of the passivation layer 181.

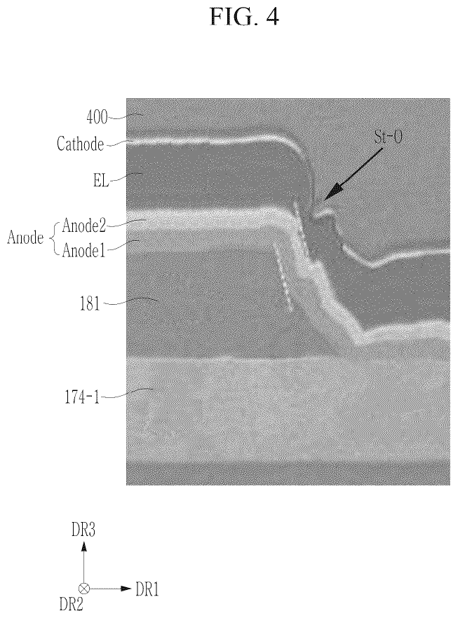

The actual stacked structure of the conductive layer stacked on the upper edge St-O of the third opening OPpvx of the passivation layer 181 will be examined through FIG. 4.

FIG. 4 is a schematic photograph of a cross-section of a portion of a light emitting display device.

In FIG. 4, only the passivation layer 181 may be positioned on the auxiliary driving low-voltage line 174-1, and no via layer 182 may be formed. In FIG. 4, an anode electrode Anode, an intermediate layer EL, and a cathode electrode Cathode included in the light emitting diode may be positioned sequentially on the passivation layer 181 in the third direction DR3. An encapsulation layer 400 may be formed on the cathode electrode Cathode to block external moisture and/or moisture from entering the organic light emitting layer in the intermediate layer EL.

In the structure of FIG. 4, the anode electrode Anode includes a lower anode electrode layer Anode1 containing a metal material and an upper anode electrode layer Anode2 formed of a transparent conductive oxide layer. Although the connection electrode CE is not shown in the structure of FIG. 4, it may have a double-layer structure like an anode electrode.

Referring to the dotted line in FIG. 4, the boundary surface of the passivation layer 181 may form a steep slope, formed at an angle close to 90 degrees (between 70 and 90 degrees), and the cathode electrode Cathode among the conductive layers formed above the upper edge St-O of the boundary surface of the passivation layer 181 may be formed to bend sharply so that it is evident that there is a structure where the thickness decreases above the upper edge St-O of the passivation layer 181 boundary surface, making it highly susceptible to disconnection. Accordingly, at least a portion of the upper edge St-O of the boundary surface of the passivation layer 181 may be formed to have a structure covered with the via layer 182 so that the cathode electrode Cathode may be positioned without disconnection. In FIG. 4, the anode electrode Anode may be shown with a low possibility of disconnection above the upper edge St-O of the passivation layer 181 boundary, as it has a double-layer structure, but there is still a possibility of disconnection in case that it has a single-layer structure. This possibility of disconnection of the anode electrode may also be applied to the connection electrode CE formed of the same material in the same layer. Therefore, as shown in FIG. 2, by covering at least part of the boundary of the third opening OPpvx of the passivation layer 181 with the via layer 182, the connection electrode CE may be formed to electrically connect with the auxiliary driving low-voltage line 174-1 only through the second opening OPvia of the via layer 182, thereby reducing the possibility of disconnection of the connection electrode CE.

Referring to FIG. 1, the third opening OPpvx of the passivation layer 181 may be formed longer in the first direction DR1 compared to the second opening OPvia of the via layer 182, the portions positioned on both sides in the first direction DR1 of the boundary of the third opening OPpvx of the passivation layer 181 may be covered by the via layer 182, and the connection electrode CE and cathode electrode Cathode positioned above this area are not susceptible to disconnection, thereby being electrically connected through this area, which has the advantage of preventing overall disconnection.

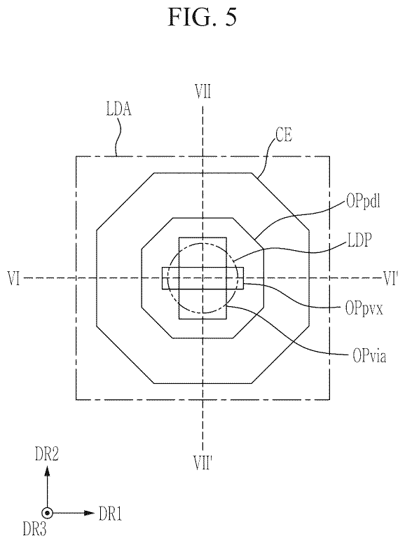

Hereinafter, the structure in which processing holes are additionally formed by laser drilling in the structure of FIG. 1 will be examined through FIGS. 5 to 7.

FIG. 5 is a schematic plan view after laser drilling in FIG. 1.

In FIG. 5, in addition to FIG. 1, a processing hole LDP formed by laser drilling may be shown. The processing hole LDP may be a circular structure in a plan view and may have a different planar shape from the second opening OPvia of the via layer 182 and the third opening OPpvx of the passivation layer 181.

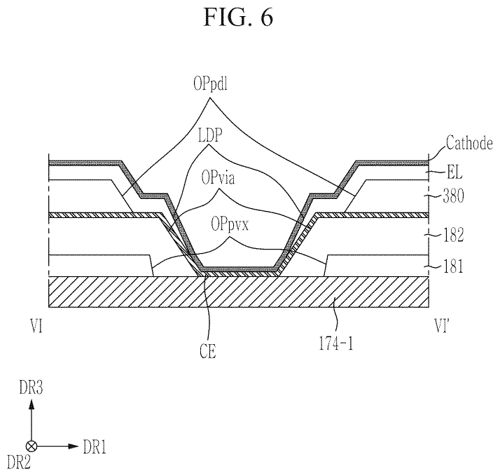

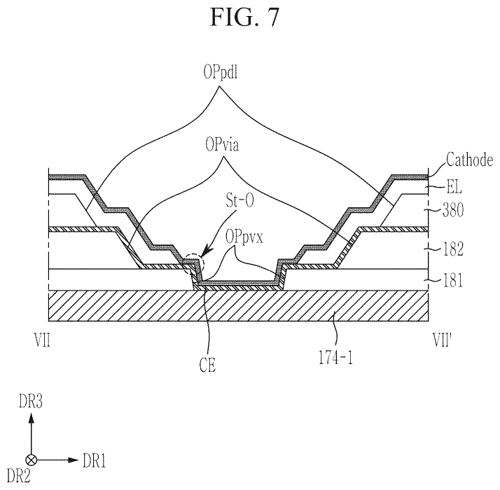

The cross-sectional structure after laser drilling as shown in FIG. 5 is examined through FIGS. 6 and 7.

FIGS. 6 and 7 are schematic cross-sectional views taken along cross-sectional lines of FIG. 5.

FIG. 6 is a schematic cross-sectional view taken along cross-sectional line VI-VI′ of FIG. 5, and FIG. 7 is a schematic cross-sectional view taken along cross-sectional line VII-VII′.

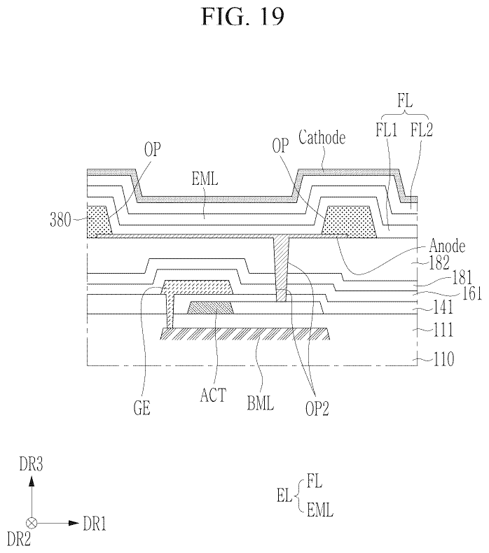

In FIG. 6 and FIG. 7, compared to FIGS. 2 and 3, an intermediate layer EL and a cathode electrode Cathode may be further formed. A processing hole LDP formed by laser drilling may be formed in the intermediate layer EL so that the cathode electrode Cathode and the connection electrode CE may be electrically connected through the processing hole LDP. As shown in FIG. 19, the intermediate layer EL may be positioned above the anode electrode Anode and the pixel defining layer 380, and in case that the intermediate layer EL may be opened by laser drilling, a processing hole LDP may be formed, which allows the structure where the cathode electrode Cathode and the connection electrode CE are electrically connected.

Compared to FIG. 6, in FIG. 7, the upper edge St-O of the interface of the passivation layer 181 may be exposed, and a connection electrode CE and a cathode electrode Cathode may be stacked thereon. Near the boundary of the upper edge St-O of the passivation layer 181, the connection electrode CE and cathode electrode Cathode may be disconnected, and at least a part may be formed so that the boundary of the upper edge St-O of the passivation layer 181 may be covered by the via layer 182.

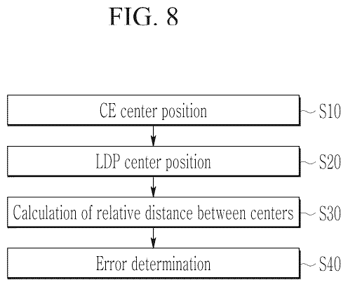

The location of the processing hole LDP shown in FIGS. 5 to 7 may be positioned near the center of the second opening OPvia of the via layer 182 and the third opening OPpvx of the passivation layer 181. However, in actual laser drilling, the position of the processing hole LDP formed due to a process error may be formed at a different location. Therefore, it is desirable to determine whether the actually formed processing hole LDP was formed without a problem, and a method of determining whether there is an error in laser drilling according to one embodiment is shown in FIG. 8.

FIG. 8 is a schematic flow chart illustrating a method for determining whether there is an error in laser drilling according to an embodiment.

Referring to FIG. 8, the method for determining errors in laser drilling according to an embodiment may include the steps of identifying the central position of the connection electrode CE (step S10), identifying the central position of the processing hole LDP formed by laser drilling (step S20), calculating the relative distance between the center of the connection electrode CE and the center of the processing hole LDP (step S30), and determining the presence of errors in laser drilling based on the calculated relative distance (step S40).

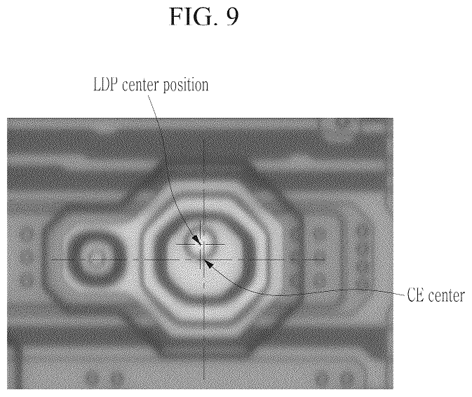

A method for determining errors in laser drilling shown in FIG. 8 will be examined using FIG. 9.

FIG. 9 is a schematic diagram illustrating each center in one embodiment.

FIG. 9 is a photograph of a laser drilling area of a light emitting display panel where laser drilling has been performed to form a processing hole LDP, and the center of the processing hole LDP and the center of the connection electrode CE are indicated.

Referring to FIGS. 8 and 9, the step S10 of determining the center position of the connection electrode CE among the methods for judging errors in laser drilling may be a step of determining the position of the center of the connection electrode CE as shown in FIG. 9, after identifying the boundary of the connection electrode CE in the laser drilling area.

The step S20 of identifying the central position of the processing hole LDP formed by laser drilling may involve confirming the boundary of the processing hole LDP formed by laser drilling in the laser drilling area, and then using this to determine the central position of the processing hole LDP as shown in FIG. 9.

Regarding the step of determining the center position of the connection electrode CE (step S10) and the step of determining the center position of the processing hole LDP (step S20), it does not matter which step is performed first, and thus the two steps (step S10, step S20) may be performed simultaneously or interchangeably.

The step S30 of calculating the relative distance between the center of the connection electrode CE and the center of the processing hole LDP may be a step that proceeds after the step S10 of identifying the center position of the connection electrode CE and the step S20 of identifying the center position of the processed hole LDP. The step S30 of calculating the relative distance may involve using the coordinates of the centers of the connection electrode CE and the processing hole LDP, which are determined respectively in the step S10 of identifying the center position of the connection electrode CE and the step S20 of identifying the center position of the processing hole LDP, to calculate the distance between the two centers.

For example, the center position of the connection electrode CE may be relatively constant in the plurality of laser drilling areas. In contrast, the position of the processing hole LDP formed by laser drilling may have a relatively large change in position in each laser drilling area. For example, the process of forming the connection electrode CE may be performed by depositing conductive material, exposing/developing using a mask to form photoresist, and then patterning the conductive material using the photoresist, which is a process for forming fine patterns and has relatively small process errors. On the other hand, the process of performing laser drilling may have a relatively large process error so that the location of the processing hole LDP formed by laser drilling may vary depending on the laser drilling area. Therefore, the distance calculated in the step S30 of calculating the relative distance may be used as a standard for confirming where the processing hole LDP is formed in the corresponding laser drilling area.

Therefore, through the step S40 of determining whether there is an error in laser drilling based on the calculated relative distance, it may be confirmed where the processing hole LDP is formed in the corresponding laser drilling area based on the calculated relative distance. For example, in case that the calculated relative distance is greater than a certain value, it may be determined as an error that laser drilling was performed outside the error range.

The key to determine the above laser drilling error may be the step of determining the center position of the connection electrode CE (step S10) and the step of determining the center position of the processing hole LDP (step S20), and the boundary of the connection electrode CE and the boundary of the processing hole LDP must be recognized separately so that the location of each center may be identified. In case that it is difficult to recognize the boundary of the connection electrode CE or the boundary of the processing hole LDP, an error in laser drilling may not be determined using the method of FIG. 8. The connection electrode CE may be largely formed in the laser drilling area, making it easy to recognize the boundaries, but the boundaries of the processing hole LDP may overlap other openings (the second opening OPvia of the via layer 182 and/or the third opening OPpvx of the passivation layer 181) (see FIG. 13), making it difficult to accurately recognize the boundaries of the processing hole LDP.

The shape of the second opening OPvia of the via layer 182 and/or the third opening OPpvx of the passivation layer 181 may be formed in a shape different from the circular shape of the processing hole LDP so as to clearly determine whether there is an error in laser drilling. For example, in the embodiment of FIG. 5, the second opening OPvia of the via layer 182 and the third opening OPpvx of the passivation layer 181 may be each formed in a rectangular shape elongated in one direction. As a result, it is possible to clearly check the center position of the processing hole LDP to confirm whether laser drilling has been performed appropriately and to prevent problems caused by laser drilling.

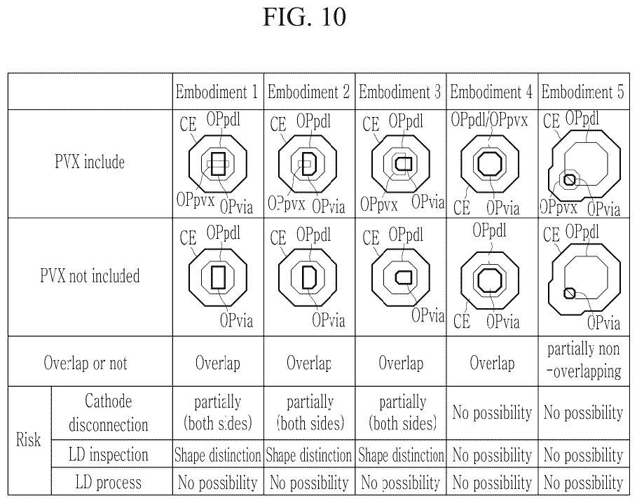

In the above, the structure of the laser drilling area LDA was examined focusing on the structure of FIG. 1. However, various embodiments are possible in other embodiments, and hereinafter, five embodiments and their characteristics, including the embodiment of FIG. 1, will be described in FIG. 10.

FIG. 10 is a schematic table summarizing various embodiments and their characteristics.

In FIG. 10, embodiments 1 through 5 (e.g., Embodiments 1 to 5) are shown, and each embodiment displays structure including the passivation layer 181 with a third opening OPpvx formed in the passivation layer 181 (e.g., PVX include of FIG. 10), and structure not including the passivation layer 181 (e.g., PVX not included of FIG. 10).

The structure (e.g., PVX of FIG. 10) including the passivation layer 181 will be examined.

Embodiment 1 (e.g., Embodiment 1 of FIG. 10) may have the same planar structure as FIG. 1 described above. Embodiments 2 and 3 (e.g., Embodiments 2 and 3 of FIG. 10) may be embodiments in which the planar shape of the second opening OPvia of the via layer 182 and/or the third opening OPpvx of the passivation layer 181 is changed from embodiment 1, and the connection electrode CE and the first opening OPpdl of the pixel defining layer 380 may have the same shape as embodiment 1 of FIG. 1.

In embodiment 2, the second opening OPvia of the via layer 182 may have an octagonal shape cut in the vertical direction, and the third opening OPpvx of the passivation layer 181 may have a rectangular shape that is elongated in the horizontal direction. The second opening OPvia of the via layer 182 may be formed to be wider in the vertical direction than the third opening OPpvx of the passivation layer 181. It may be seen that a portion of the third opening OPpvx of the passivation layer 181 does not overlap the second opening OPvia of the via layer 182 and thus has a structure covered with the via layer 182.

In embodiment 3, the third opening OPpvx of the passivation layer 181 may have an octagonal shape cut in the vertical direction, the second opening OPvia of the via layer 182 may have a structure elongated in the horizontal direction, and the second opening OPvia of the via layer 182 may be formed with a narrow width in the vertical direction compared to the third opening OPpvx of the passivation layer 181. In embodiment 3, it may be seen that at least a portion of the third opening OPpvx of the passivation layer 181 does not overlap the second opening OPvia of the via layer 182, and thus has a structure covered by the via layer 182.

In embodiments 1 to 3, the second opening OPvia of the via layer 182 and/or the third opening OPpvx of the passivation layer 181 may not have a circular shape, and their different planar shapes makes it easy to distinguish them from the machined holes formed by laser drilling.

Meanwhile, embodiment 4 (e.g., Embodiment 4 of FIG. 10) may have a structure where the third opening OPpvx of the passivation layer 181 aligns with the first opening OPpdl of the pixel defining layer 380 in a plan view, and the second opening OPvia of the via layer 182 may be positioned in the third opening OPpvx of the passivation layer 181 and the first opening OPpdl of the pixel defining layer 380 in a plan view. Therefore, in embodiment 4, it may be seen that the boundary of the third opening OPpvx of the passivation layer 181 does not overlap the second opening OPvia of the via layer 182, and thus has a structure covered with the via layer 182.

In embodiment 4, the second opening OPvia of the via layer 182 and the third opening OPpvx of the passivation layer 181 each may have an octagonal shape so that the actually formed planar shape may approximate a circular shape, and it may be indistinguishable from the machined hole and planar shape formed by laser drilling. However, in embodiment 4, the second opening OPvia of the via layer 182 and the third opening OPpvx of the passivation layer 181 may be formed to be the same size as or at least about 80% the size of the first opening OPpdl of the pixel defining layer 380, and may be formed significantly larger than the size of the processing hole and may be easily distinguished from the processing hole.

Embodiment 5 (e.g., Embodiment 5 of FIG. 10), unlike the previous embodiments, may have a structure where some of the second opening OPvia of the via layer 182 and the third opening OPpvx of the passivation layer 181 are formed in positions that do not overlap the first opening OPpdl of the pixel defining layer 380 in a plan view, protruding outward. For example, a part of the second opening OPvia of the via layer 182 and the third opening OPpvx of the passivation layer 181 overlap the first opening OPpdl of the pixel defining layer 380 in a plan view, but the remaining part may not overlap the first opening OPpdl of the pixel defining layer 380. In embodiment 5, the second opening OPvia of the via layer 182 and the third opening OPpvx of the passivation layer 181 may be electrically connected to the connection electrode CE corresponding to the portion protruding outward from the first opening OPpdl of the pixel defining layer 380 in a plan view and may also have a structure that further includes extended parts.

Based on FIGS. 6 and 7, the light emitting display devices according to embodiments 1 to 4 may include a substrate (see 110 in FIG. 19), a voltage line positioned on the substrate that delivers a constant voltage (for example, auxiliary driving low-voltage line 174-1), a passivation layer 181 positioned on the voltage line, a via layer 182 positioned on the passivation layer 181, a connection electrode CE positioned on the via layer 182, a pixel defining layer 380 positioned above the connection electrode CE, and a cathode electrode Cathode positioned on the pixel defining layer 380. The pixel defining layer 380 may have a first opening OPpdl that overlaps the connection electrode CE in a plan view, the via layer 182 may have a second opening OPvia that overlaps the connection electrode CE in a plan view, the passivation layer 181 may have a third opening OPpvx that overlaps the connection electrode CE in a plan view, the cathode electrode Cathode and the connection electrode CE may be electrically connected through the first opening OPpdl of the pixel defining layer 380, the voltage line and the connection electrode CE may have electrically connected through the second opening OPvia of the via layer 182 and the third opening OPpvx of the passivation layer 181, and the third opening OPpvx of the passivation layer 181 may not overlap at least partially with the second opening OPvia of the via layer 182 in a plan view. For example, the second opening OPvia of the via layer 182 and the third opening OPpvx of the passivation layer 181 may be positioned in the first opening OPpdl of the pixel defining layer 380 in a plan view. The second opening OPvia of the via layer 182 and the third opening OPpvx of the passivation layer 181 may have a planar shape rather than a circle. For example, the second opening OPvia of the via layer 182 may have various polygonal planar shapes such as triangles, rectangles, hexagons, and octagons, or a planar shape with polygonal shapes cut out.

Based on FIGS. 6 and 7, the light emitting display device according to embodiment 5 may include a substrate (see 110 in FIG. 19), a voltage line positioned on the substrate that delivers a constant voltage (for example, an auxiliary driving low-voltage line 174-1), a passivation layer 181 positioned on the voltage line, a via layer 182 positioned on the passivation layer 181, a connection electrode CE positioned on the via layer 182, a pixel defining layer 380 positioned on the connection electrode CE, and a cathode electrode Cathode positioned on the pixel defining layer 380. The pixel defining layer 380 may have a first opening OPpdl that overlaps the connection electrode CE in a plan view, the via layer 182 may have a second opening OPvia that overlaps the connection electrode CE in a plan view, and the passivation layer 181 has a third opening OPpvx that overlaps the connection electrode CE in a plan view. The cathode electrode Cathode and the connection electrode CE may be electrically connected through the first opening OPpdl of the pixel defining layer 380, the voltage line and the connection electrode CE may be electrically connected through the second opening OPvia of the via layer 182 and the third opening OPpvx of the passivation layer 181, and at least part of the second opening OPvia and/or the third opening OPpvx of the passivation layer 181 may have a structure that does not overlap the first opening OPpdl of the pixel defining layer 380 in a plan view.

Meanwhile, the structure not including the passivation layer 181 (PVX not included) is as follows.

In each of embodiments 1 to 5 (e.g., Embodiments 1 to 5 of FIG. 10), the third opening OPpvx of the passivation layer 181 may be omitted, and in embodiments 1 to 3 (e.g., Embodiments 1 to 3), the second opening OPvia of the via layer 182 may have a planar shape rather than a circle, and may be plane-distinct from the processing hole and in embodiment 4 (e.g., Embodiment 4 of FIG. 10), the second opening of the via layer 182 may have an octagonal shape and may be similar to a circle, but its size-distinct from the processing hole by having a size corresponding to the first opening OPpdl of the pixel defining layer 380.

Based on FIGS. 6 and 7, the light emitting display devices according to embodiments 1 to 4 (e.g., Embodiments 1 to 4 of FIG. 10), which do not include a passivation layer 181 (e.g., PVX not included of FIG. 10), may comprise a substrate (see 110 in FIG. 19), a voltage line positioned on the substrate that delivers a constant voltage (for example, auxiliary driving low-voltage line 174-1), a via layer 182 positioned above the voltage line, a connection electrode CE positioned above the via layer 182, a pixel defining layer 380 positioned above the connection electrode CE, and a cathode electrode Cathode positioned above the pixel defining layer 380. The pixel defining layer 380 may have a first opening OPpdl that overlaps the connection electrode CE in a plan view, the via layer 182 may have a second opening OPvia that overlaps the connection electrode CE in a plan view, the cathode electrode Cathode and the connection electrode CE may have electrically connected through the first opening OPpdl of the pixel defining layer 380, the voltage line and the connection electrode CE may be electrically connected through the second opening OPvia of the via layer 182, and the second opening OPvia of the via layer 182 may have a non-circular planar shape. For example, the second opening OPvia of the via layer 182 may have various polygonal planar shapes such as triangles, rectangles, hexagons, and octagons, or a planar shape with polygonal shapes cut out.

In embodiment 5 (e.g., Embodiment 5 of FIG. 10), the second opening OPvia of the via layer 182 may have a portion protruding outward from the first opening OPpdl of the planar pixel defining layer 380 such that part of the second opening OPvia of the via layer 182 may not overlap the first opening OPpdl of the pixel defining layer 380 in a plan view.

Based on FIGS. 6 and 7, the light emitting display device according to embodiment 5, which does not include a passivation layer 181 (e.g., PVX not included of FIG. 10), may comprise a substrate (see 110 in FIG. 19), a voltage line positioned above the substrate and delivering a constant voltage (for example, an auxiliary driving low-voltage line 174-1), a via layer 182 positioned above the voltage line, a connection electrode CE positioned on the via layer 182, a pixel defining layer 380 on top of the connection electrode CE, and a cathode electrode Cathode positioned above the pixel defining layer 380, the pixel defining layer 380 may have a first opening OPpdl that overlaps the connection electrode CE in a plan view. The via layer 182 may have a second opening OPvia that overlaps the connection electrode CE in a plan view, the cathode electrode and the connection electrode CE may be electrically connected through the first opening OPpdl of the pixel defining layer 380, the voltage line and the connection electrode CE may be electrically connected through the second opening OPvia of the via layer 182, and at least part of the second opening OPvia of the via layer 182 may have a structure that does not overlap the first opening OPpdl of the pixel defining layer 380 in a plan view.

Looking at the respective widths of the first opening OPpdl of the pixel defining layer 380 in one direction in embodiments 1 to 5 of FIG. 10, the widths may be as follows.

Except for embodiment 5, all may have the same width, and in embodiment 5, a portion of the second opening OPvia of the via layer 182 and/or the third opening OPpvx of the passivation layer 181 may protrude to the outside of the first opening OPpdl of the pixel defining layer 380, and the first opening OPpdl of the pixel defining layer 380 may also be formed to be slightly larger.

In embodiments 1 to 5 of FIG. 10, the area of each connection electrode CE may be as follows.

Embodiments 1 to 4 may have the same area, but in embodiment 5, the connection electrode CE may be a part of the second opening OPvia of the via layer 182 and/or the third opening OPpvx of the passivation layer 181, and the connection electrode CE may also be formed to be slightly larger while protruding outside the first opening OPpdl of the pixel defining layer 380.

With respect to embodiments 1 to 5 as described above, FIG. 10 additionally describes the items “Overlap or not,” “Cathode disconnection,” “LD inspection,” and “LD process.”

“Overlap or not” may refer to whether the first opening OPpdl of the pixel defining layer 380 and the second opening OPvia of the via layer 182 or the third opening OPpvx of the passivation layer 181 overlap in a plan view, and embodiments 1 to 4 all overlap, but only embodiment 5 may have a structure where they partially do not overlap.

“Cathode disconnection,” “LD inspection,” and “LD process” may be used to determine whether there is a risk of defects occurring during the actual manufacturing process in each embodiment, and each has the following meaning.

As shown in FIG. 4, “Cathode disconnection” may refer to whether the cathode electrode Cathode may be disconnected due to the upper edge St-O of the passivation layer 181 interface, which represents an embodiment with no potential for disconnection and some embodiments with potential for disconnection in some areas.

In embodiment 1, the upper and lower boundaries of the third opening OPpvx of the passivation layer 181 may be exposed by the second opening OPvia of the via layer 182 so that there is a possibility of disconnection on both sides. However, in embodiment 1, the left and right boundaries of the third opening OPpvx of the 181 may be positioned outside the second opening OPvia of the via layer 182 and may be covered with the via layer 182 so that there is no possibility of disconnection at this part. Therefore, it is possible to have a structure in which the cathode electrode Cathode is electrically connected through this part. In embodiments 2 and 3, the right and left boundaries of the third opening OPpvx of the passivation layer 181 may be exposed by the second opening OPvia of the via layer 182 so that there is a possibility of disconnection on one side. However, since the other part of the third opening OPpvx of the passivation layer 181 may be positioned outside the second opening OPvia of the via layer 182 and may be covered with the via layer 182, there is no possibility of disconnection in this part. In embodiments 4 and 5, the boundaries of the third opening OPpvx of the passivation layer 181 may be all positioned outside the second opening OPvia of the via layer 182 so that there is no possibility of disconnection.

“LD inspection” may indicate whether the method shown in FIG. 8 for determining the presence of errors in laser drilling clearly identifies such errors. “Shape distinction” may indicate that the shape of the second opening OPvia of the via layer 182 and/or the third opening OPpvx of the passivation layer 181 is formed differently from the circular shape of the processing hole LDP, allowing the boundaries and center of the processing hole LDP to be identified, thus enabling the determination of errors in laser drilling. “No possibility” may indicate an example where differences in size or position from the processing hole LDP allow the boundaries and center of the processing hole LDP to be identified, thus enabling the determination of errors in laser drilling.

“LD process” may indicate whether there is a possibility of problems occurring during the laser drilling process, but since each embodiment is formed without problems in the laser drilling process, all are described as “no possibility.”

Referring to FIG. 10 above, in embodiments 1 to 5, overlapping openings OPpdl, OPvia, and OPpvx may be positioned in the laser drilling area, and the connection electrode CE may be electrically connected to the lower auxiliary driving low-voltage line 174-1 since the structure and the structure electrically connected to the upper cathode electrode Cathode are positioned to overlap each other, the area of the laser drilling area may be formed to be narrow, which may have the advantage of enabling laser drilling even in high-resolution light emitting display devices.

Embodiments 1 to 3 may have the advantage of being able to identify the center of the processing hole LDP due to the difference in shape, as the shape of the second opening OPvia of the via layer 182 and/or the third opening OPpvx of the passivation layer 181 is formed differently from the circular shape of the processing hole LDP. As a result, it is possible to determine the presence of errors in laser drilling in a method like that shown in FIG. 8. In embodiments 1 to 3, a portion of the third opening OPpvx of the passivation layer 181 may protrude in a plan view so as not to overlap the second opening OPvia of the via layer 182, and the third opening OPpvx of the passivation layer 181 is at that portion, the boundary of is covered with the via layer 182 so that the conductive layer positioned at the top may have a structure in which it is electrically connected without being disconnected.

Embodiments 4 and 5 may have a processing hole LDP and openings (the second opening OPvia of the via layer 182 and/or the third opening OPpvx of the passivation layer 181) that are different in size or location.

In FIG. 4, an opening of a different size from the processing hole may be included. Thus, embodiment 4 may have the advantage of being able to identify whether there is an error in laser drilling in a manner similar to that shown in FIG. 8, as the size of the second opening OPvia in the via layer 182 and the third opening OPpvx in the passivation layer 181 are formed to be the same or equivalent to the size of the first opening OPpdl in the pixel defining layer 380, and are formed larger than the processing hole, thereby easily distinguishing them from the processing hole. The third opening OPpvx of the passivation layer 181 may be formed larger than the second opening OPvia of the via layer 182 so that all boundaries of the third opening OPpvx of the passivation layer 181 are covered by the via layer 182, allowing the conductive layer positioned above to have a structure that is electrically connected without being disconnected.

Embodiment 5 may include an opening whose location is different from that of the processing hole. For example, embodiment 5 may have a structure in which a portion of the second opening OPvia of the via layer 182 and the third opening OPpvx of the passivation layer 181 are formed in a position that does not overlap in a plan view with the first opening OPpdl of the pixel defining layer 380 and protrude outward. As a result, it may be readily distinguished from the processing hole and has the advantage of being able to determine whether there is an error in laser drilling using the method shown in FIG. 8. The third opening OPpvx of the passivation layer 181 may be formed larger than the second opening OPvia of the via layer 182 so that all the boundaries of the third opening OPpvx of the passivation layer 181 are covered by the via layer 182, allowing the conductive layer positioned above to be electrically connected without being disconnected.

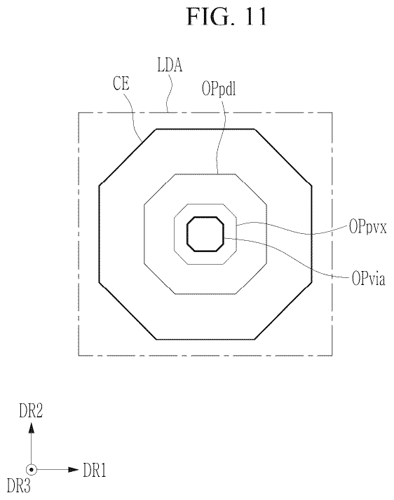

The structure of the comparative example and the relationship between the processing hole and the opening in the comparative example will be examined using FIGS. 11 to 13.

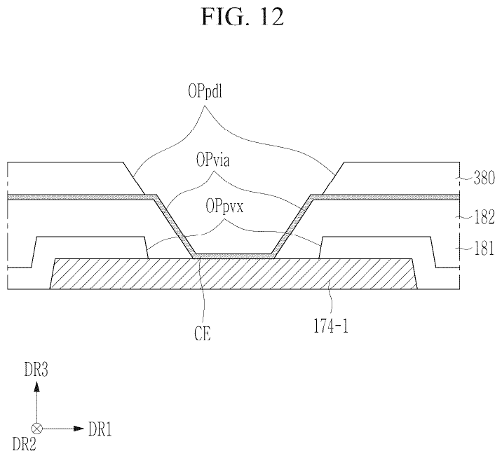

FIG. 11 is a schematic plan view showing the structure of the laser drilling area according to a comparative example, FIG. 12 is a schematic cross-sectional view of the comparative example of FIG. 11, and FIG. 13 is a schematic photograph taken after laser drilling was performed in the comparative example of FIG. 11.

Referring to FIGS. 11 and 12, the planar structure (e.g., structure in a plan view) of the comparative example, unlike the embodiments in FIG. 1 and embodiments 1 to 5 in FIG. 10, may have a structure where the machined holes formed by laser drilling are not different in shape, position, or size.

FIG. 13 is a schematic photograph taken after the processing hole LDP has been formed in a comparative example, and the processing hole LDP overlaps the openings OPvia, OPpvx, and their shapes and sizes are similar, making it difficult to clearly identify the boundaries of the processing hole LDP.

For example, in the comparative example, the second opening OPvia of the via layer 182 and the third opening OPpvx of the passivation layer 181 may have an octagonal shape, which is technically different from the circular-shaped processing hole, but in the actual photograph (see FIG. 13), it is difficult to distinguish between processing holes and second openings OPvia and OPpvx because they all have circular or similar shapes. In the comparative example, the sizes of the processing holes and second openings OPvia and OPpvx may be not sufficiently different to be readily distinguished, and their positions may be formed at overlapping positions, making them difficult to distinguish.

As a result, even if the method of determining laser drilling errors as shown in FIG. 8 is used, it may have the disadvantage of making it difficult to determine whether there are laser drilling errors because it is difficult to check the center of the processing hole.

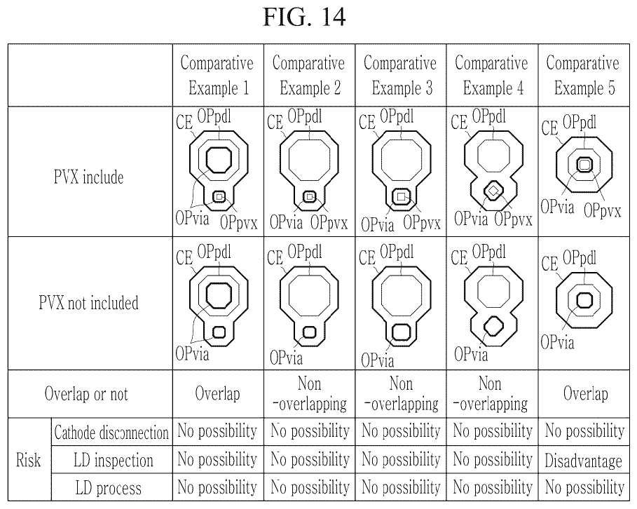

The shapes of the comparative examples may vary beyond those in FIGS. 11 and 12, and various comparative examples will be examined through FIG. 14.

FIG. 14 is a schematic table summarizing various comparative examples and their characteristics.

In FIG. 14, comparative examples 1 through 5 (e.g., Comparative Examples 1 to 5 of FIG. 14) are included, and each example is shown distinguishing between a structure (e.g., PVX include of FIG. 14) that includes a passivation layer 181 and in which the third opening OPpvx of the passivation layer 181 is formed, and a structure (e.g., PVX not included of FIG. 14) that does not include a passivation layer 181.

Comparative example 5, which includes the passivation layer 181, is the same as the comparative example of FIG. 11.

In FIG. 14, a table corresponding to the table in FIG. 10, is described by comparing the same items as in FIG. 10.

In each comparative example, the width in one direction of the first opening OPpdl of the pixel defining layer 380 may be as follows.

In each comparative example of FIG. 14, the size of the first opening OPpdl of the pixel defining layer 380 may vary, and thus the width may also vary. Comparative example 1 and comparative example 2 may have the same width for the first opening OPpdl of the pixel defining layer 380, and comparative example 3 and comparative example 5 may have the same width for the first opening OPpdl of the pixel defining layer 380. Based on the width of the first opening OPpdl of the pixel defining layer 380, comparative example 1 and comparative example 2 may have the largest values, comparative example 3 and comparative example 5 may have intermediate values, and comparative example 4 may have the smallest value.

The area of the connection electrode CE in each comparative example of FIG. 14 may be as follows.

In each comparative example of FIG. 14, the area of the connection electrode CE may vary. Based on the area of the connection electrode CE, the area may become smaller in the order of comparative example 1, comparative example 2, comparative example 3, comparative example 4, and comparative example 5.

As shown in FIG. 10 and in FIG. 14 as well, it is possible to know whether the first opening OPpdl of the pixel defining layer 380 and the second opening OPvia of the via layer 182 or the third opening OPpvx of the passivation layer 181 overlap on the plane through the “Overlap or not.”

For example, comparative example 1 and comparative example 5 may have the first opening OPpdl of the pixel defining layer 380 and the second opening OPvia of the via layer 182 or the third opening OPpvx of the passivation layer 181 overlapping in a plan view, but comparative examples 2 to 4 have a structure where the first opening OPpdl of the pixel defining layer 380 and the second opening OPvia of the via layer 182 or the third opening OPpvx of the passivation layer 181 do not overlap in a plan view (“Non-overlapping”).

A risk of defects occurring during the actual manufacturing process may be examined through “Cathode disconnection,” “LD inspection,” and “LD process.”

A “Cathode disconnection” may not happen in each comparative example, as in comparative examples 1 to 4, a separate connection electrode CE may be electrically connected to the lower auxiliary driving low-voltage line 174-1, which results in the third opening OPpvx of the passivation layer 181 being formed larger than the second opening OPvia of the via layer 182, and the boundary of the third opening OPpvx of the passivation layer 181 being covered by the via layer 182, which ensures that the conductive layer positioned above does not disconnect and remains electrically connected. In comparative example 5, the third opening OPpvx of the passivation layer 181 may be formed larger than the second opening OPvia of the via layer 182 so that the conductive layer positioned at the top is electrically connected without being disconnected.

The method of determining whether there are errors in laser drilling as shown in FIG. 8 through the “LD inspection” is described along with whether it is possible to clearly identify the errors in laser drilling. Comparative examples 1 to 4 may distinguish the positions where the processing holes are to be formed (inside the first opening OPpdl of the pixel defining layer 380) and the third opening OPpvx of the passivation layer 181 and/or the second opening OPvia of the via layer 182 so there is no problem in recognizing the boundaries of the processing holes. As a result, a laser drilling error may be clearly confirmed by applying the method for determining whether there is a laser drilling error in FIG. 8. However, comparative example 5 may have a small area of laser drilling, but in case that the processing hole is formed, as shown in FIG. 13, the processing hole may overlap the third opening OPpvx of the passivation layer 181 and/or the second opening OPvia of the via layer 182, making it difficult to recognize the boundaries of the processing hole, thus making it difficult to apply the method of determining the errors in laser drilling shown in FIG. 8.

In each comparative example, “LD process” may indicate whether there is a possibility of problems occurring during the laser drilling process, but since each comparative example is also structured without problems in the laser drilling process, all are described as “No possibility.”

Referring to FIG. 14 above, each comparative example may have the following characteristics.

Comparative examples 1 to 4 may show where the first opening OPpdl of the pixel defining layer 380 is formed for the connection electrode CE to connect to the cathode electrode Cathode and the position of the second opening OPvia of the via layer 182 and/or the third opening OPpvx of the passivation layer 181 for the connection electrode CE to connect to the lower auxiliary driving low-voltage line 174-1. Comparative example 1, unlike comparative examples 2 to 4, may differ in that it also forms the second opening OPvia of the via layer 182 overlapping the connection electrode CE and/or the third opening OPpvx of the passivation layer 181. However, comparative examples 1 to 4 may have a disadvantage in that the area occupied by the laser drilling area is larger than that of the embodiment, making it difficult to apply in a high-resolution light emitting display device.

Comparative example 5 may show that, as in the embodiments, there may be an overlap of the position where the first opening OPpdl of the pixel defining layer 380 is formed for the connection electrode CE to be electrically connected to the cathode electrode Cathode, and the position of the second opening OPvia in the via layer 182 and/or the third opening OPpvx in the passivation layer 181 for the connection electrode CE to connect to the lower auxiliary driving low-voltage line 174-1 enabling laser drilling even in high-resolution light emitting display devices. However, as seen in FIG. 13, it is difficult to clearly confirm the boundary of the processing hole LDP formed by laser drilling so that it is desirable to determine whether there is an error in laser drilling using the method of determining the error in laser drilling as shown in FIG. 8. As a result, it has the disadvantage of being unable to determine errors, making it difficult to detect problems such as short circuits in the actual panel.

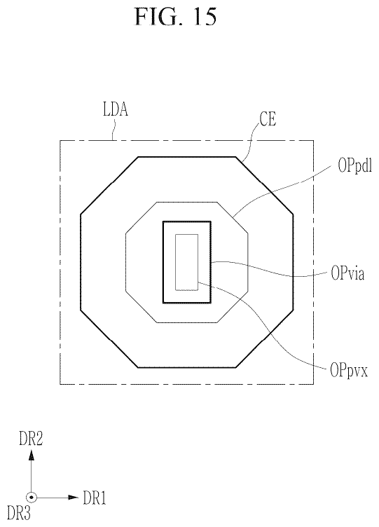

In the following, the structure of a comparative example with a high possibility of disconnection will be examined through FIG. 15.

FIG. 15 is a schematic plan view showing the structure of a laser drilling area according to another comparative example.

The comparative example of FIG. 15 may be similar to the embodiment of FIG. 1, but the third opening OPpvx of the passivation layer 181 may have a rectangular shape elongated in the second direction DR2 like the second opening OPvia of the via layer 182, and the third opening OPpvx of the passivation layer 181 is positioned in the second opening OPvia of the via layer 182. Therefore, the cross-sectional structure of the comparative example in FIG. 15 may correspond to FIGS. 3 and 7.

In comparative example of FIG. 15, the third opening OPpvx of the passivation layer 181 and the second opening OPvia of the via layer 182 may have a rectangular shape, which may be distinguished from the circular shape of the processing hole, allowing the determination of any errors in laser drilling using the method of judging errors in laser drilling shown in FIG. 8. However, the third opening OPpvx of the passivation layer 181 may be positioned in the second opening OPvia of the via layer 182, causing the boundaries of the third opening OPpvx of the passivation layer 181 to be exposed and not entirely covered by the via layer 182. Referring to FIG. 4, as the side slope of the passivation layer 181 is formed steeply, there is a high possibility of disconnection of the conductive layer such as the cathode electrode Cathode positioned on top of the passivation layer 181. Accordingly, the comparative example of FIG. 15 may be difficult to apply to a light emitting display device unless special measures are taken, such as forming a very thick conductive layer to prevent disconnection of the upper conductive layer even on the side of the exposed first passivation layer 181.

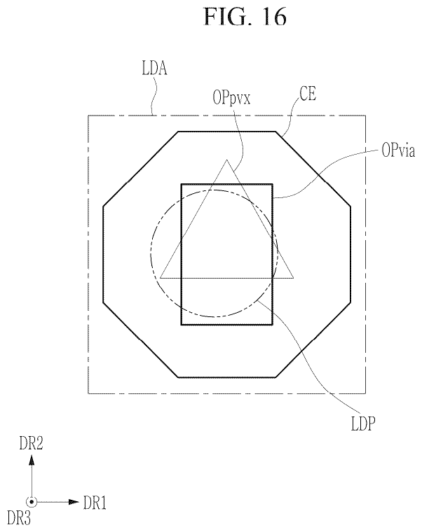

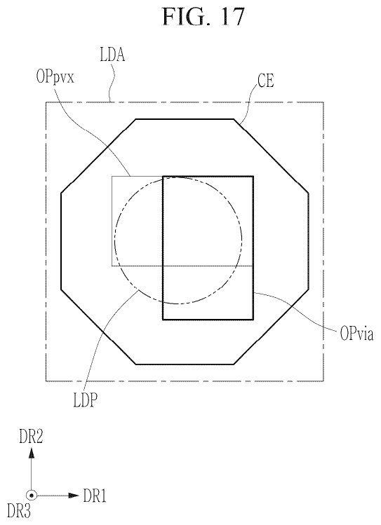

As shown in FIGS. 14 and 15, embodiments that overcome the problems occurring in the comparative examples may include, in addition to the embodiment of FIG. 1 and embodiments 1 to 5 of FIG. 10, other embodiments as well, the structure of another embodiment may be examined below through FIGS. 16 and 17.

FIGS. 16 and 17 are schematic plan views showing the structure of a laser drilling area according to another embodiment.

In the embodiments of FIGS. 16 and 17, the shape of the second opening OPvia of the via layer 182 and/or the third opening OPpvx of the passivation layer 181 may be formed in a shape different from the circular shape of the processing hole LDP.

In the embodiment of FIG. 16, the shape of the third opening OPpvx of the passivation layer 181 may be triangular so that it may be distinguished from the circular-shaped processing hole LDP. In FIG. 16, the vertex of the triangular-shaped third opening OPpvx of the first passivation layer 181 may be positioned to protrude in a plan view from the second opening OPvia of the via layer 182 so that the boundary of the third opening OPpvx of the passivation layer 181 is covered with a via layer 182, and the conductive layer positioned at the top may be electrically connected without being disconnected.

In the embodiment of FIG. 17, the shape of the third opening OPpvx of the passivation layer 181 may be rectangular, similar to the shape of the second opening OPvia of the via layer 182, but they may have structures where the direction of the longer side is extended differently. For example, the long side may mean the longest side among the sides of the planar structure of each opening. The long side of the rectangular third opening OPpvx of the first passivation layer 181 may extend in the first direction DR1, and the long side of the rectangular second opening OPvia of the via layer 182 may extend in the second direction DR2, which is perpendicular to the first direction DR1. In the embodiment of FIG. 17, the boundary of the third opening OPpvx of the passivation layer 181 and the second opening OPvia of the via layer 182 may be arranged to coincide with each other in a plan view, but according to the embodiment, they may be arranged with a horizontal spacing. In FIG. 17, the second opening OPvia of the via layer 182 and the third opening OPpvx of the passivation layer 181 may be distinguished from the circular-shaped processing hole LDP, and part of the third opening OPpvx of the passivation layer 181 may protrude from the second opening OPvia of the via layer 182 in a plan view so that the boundary of part of the third opening OPpvx of the passivation layer 181 is covered by the via layer 182 and positioned above, allowing the conductive layer positioned above to be electrically connected without being disconnected.

In other embodiments, the long-side direction may form various angles, unlike in FIG. 17, and the shape may also be formed in various shapes other than a square.

The above explanation focuses on the shape of the laser drilling area of the light emitting display device, but in the light emitting display device, a light emitting diode and a pixel driver that transmits current to the light emitting diode are formed around the laser drilling area. A pixel driver may be positioned on the substrate, a light emitting diode may be positioned on the pixel driver, and a schematic stacked structure of some layers of the light emitting display device including the pixel driver will be examined through FIGS. 18 and 19.

The mask using a schematic stacked structure and the manufacturing sequence based on FIG. 18 will be examined.

FIG. 18 is a table schematically illustrating steps for manufacturing some layers of a light emitting display device according to an embodiment.

In FIG. 18, the pixel driver positioned on the top of the substrate of the light emitting display device, the anode electrode belonging to the light emitting diode positioned above the pixel driver, and the pixel defining layer 380 that partitions the anode electrode are described.

Referring to the embodiment of FIG. 18, a lower shielding layer BML may be positioned on the substrate, and a buffer layer 111 may be positioned on the lower shielding layer BML. A semiconductor layer ACT formed of a silicon semiconductor (e.g., polycrystalline semiconductor P—Si) or an oxide semiconductor may be positioned on the buffer layer 111. A gate insulating layer 141 may be positioned on the semiconductor layer ACT, and a gate conductive layer (gate) may be positioned on the gate insulating layer 141. An interlayer insulating layer 161 may be positioned on the gate conductive layer (gate), and the data conductive layer SD may be positioned on the interlayer insulating layer 161. A passivation layer 181 and a via layer 182 may be sequentially formed on the data conductive layer SD, and an anode layer including an anode electrode and a connection electrode CE may be positioned on the via layer 182. A pixel defining layer 380 including an opening may be formed on the anode layer.

In FIG. 18, the layer using the mask is also specified, and a total of 9 masks are shown including the pixel defining layer 380. For example, the first mask may be used to form the lower shielding layer BML, the second mask may be used to form the semiconductor layer ACT, the third mask may be used to form the gate conductive layer (gate), the fourth mask may be used to form contact openings in the interlayer insulating layer 161, gate insulating layer 141, and/or buffer layer 111, the fifth mask may be used to form the data conductive layer SD, the sixth mask may be used to form contact openings in the passivation layer 181, the seventh mask may be used to form contact openings in the via layer 182, the eighth mask may be used to form the anode layer including the anode electrode and the connection electrode CE, and the ninth mask may be used to form openings in the pixel defining layer 380. Through the ninth mask, the pixel defining layer 380 may form an opening (see OP in FIG. 19) exposing the anode electrode Anode and the first opening OPpdl shown in FIG. 1.

The light emitting diode may be positioned on the pixel driver and the pixel driver of the light emitting display device having a stacked structure as shown in FIG. 18 and may have a cross-sectional structure as shown in FIG. 19.

FIG. 19 is a schematic cross-sectional view of a light emitting display device according to an embodiment.

The light emitting diode includes a cathode electrode Cathode, an intermediate layer EL including a functional layer FL and a light emitting layer EML, and an anode electrode Anode, and may be separated from adjacent light emitting diodes by a pixel defining layer 380. In the cross-sectional view of FIG. 19, the layers corresponding to the cathode electrode Cathode, the pixel defining layer 380, the intermediate layer EL including the functional layer FL and the light emitting layer EML, and the anode electrode Anode may be also called light emitting device layers.

In FIG. 19, the layer positioned below the light emitting layer—namely, below the cathode electrode Cathode—and the layer positioned further below may be also referred to as the driving device layer, where the pixel driver that generates and delivers current to the light emitting diode may be positioned. The pixel driver includes a transistor and a capacitor, and a conductive layer, a semiconductor layer, and an insulating layer constituting the transistor and the capacitor may be positioned in the driving element layer.

FIG. 19 may illustrate a simplified cross-sectional structure of one light emitting diode and one pixel driver included in one pixel with an opening OP positioned in the pixel defining layer 380, and a path through which current is transmitted from a transistor of the pixel driver to the anode electrode Anode.

FIG. 19 may show a simplified view of the structure of the lower part of the anode electrode—for example, the structure of the driving element layer—with only one transistor shown. A brief overview of the actuator layer structure from the substrate 110 to the via layer 182 is as follows.

The substrate 110 may include a material that has rigid properties and does not bend, such as glass, or may include a flexible material that may bend, such as plastic or polyimide. In the case of a flexible substrate, it may have a structure in which a two-layer structure of polyimide and a barrier layer formed of an inorganic insulating material on the repeating structure is formed.

The lower shielding layer BML containing metal may be positioned on the substrate 110, and the lower shielding layer BML may overlap in a plan view a channel of one of the transistors positioned in the pixel driver included in the pixel. In other embodiments, the driving low-voltage line to which the driving low-voltage ELVSS is applied may be positioned on the same layer as the lower shielding layer BML. For example, the driving low-voltage line may be a voltage line electrically connected to the auxiliary driving low-voltage line 174-1.

The substrate 110 and the lower shielding layer BML may be covered by the buffer layer 111. The buffer layer 111 may serve to block penetration of impure elements into the semiconductor layer ACT, and may be an inorganic insulating layer containing silicon oxide SiOₓ, silicon nitride SiNₓ, or silicon oxynitride SiONₓ.

A semiconductor layer ACT formed of a silicon semiconductor (e.g., polycrystalline semiconductor P—Si) or an oxide semiconductor may be positioned on the buffer layer 111. The semiconductor layer ACT may be a semiconductor layer positioned in a pixel driver included in a pixel, and may include a transistor channel including a driving transistor and a first region and a second region positioned on both sides of the channel. For example, the channel of the transistor may be a portion of the semiconductor layer ACT that overlaps a gate electrode GE, and the first and second regions may be portions of the semiconductor layer ACT that do not overlap the gate electrode GE. For example, the first area and the second area positioned on both sides of the channel of the semiconductor layer ACT may be not covered by the gate electrode GE and may have conductive layer characteristics through plasma treatment or doping, allowing them to serve the roles of the first electrode and the second electrode of the transistor.

A gate insulating layer 141 may be positioned on the semiconductor layer ACT and the buffer layer 111. The gate insulating layer 141 may be an inorganic insulating layer containing silicon oxide (SiOₓ), silicon nitride (SiNₓ), or silicon oxynitride (SiONₓ).

A gate conductive layer including the gate electrode GE of the transistor positioned in the pixel driver may be positioned on the gate insulating layer 141. A scan line may be formed in addition to the gate electrode GE of the transistor positioned in the pixel driver. The gate conductive layer may include one electrode of one capacitor positioned in the pixel driver. The gate conductive layer may include a metal or metal alloy such as aluminum (Al), copper (Cu), molybdenum (Mo), titanium (Ti), and may be made of a single layer or multiple layers.

After forming the gate conductive layer, a plasma treatment or doping process may be performed to make the exposed area of the semiconductor layer ACT conductive. For example, the semiconductor layer ACT covered by the gate electrode GE may not be conductive, and the portion of the semiconductor layer ACT not covered by the gate electrode GE may have the same characteristics as the conductive layer.

Openings that expose the lower shielding layer BML may be positioned in the gate insulating layer 141 and buffer layer 111, and through the openings in the gate insulating layer 141 and buffer layer 111, the gate electrode GE and the lower shielding layer BML may be electrically connected.

The interlayer insulating layer 161 may be positioned on the gate conductive layer and the gate insulating layer 141. The interlayer insulating layer 161 may include an inorganic insulating layer containing silicon oxide SiOₓ, silicon nitride SiNₓ, or silicon oxynitride SiONₓ, and in some embodiments, the inorganic insulating material may be formed thickly. In other embodiments, the interlayer insulating layer 161 may be formed of an organic insulating layer and may include one or more materials selected from the group consisting of polyimide, polyamide, acrylic resin, benzocyclobutene, and phenol resin.

The data conductive layer including a data line, the driving voltage line, and/or the auxiliary driving low-voltage line 174-1 may be positioned on the interlayer insulating layer 161. The data conductive layer may include another electrode of one capacitor positioned in the pixel driver. In other embodiments, another electrode of the capacitor may be positioned in a portion of the semiconductor layer ACT that has the same characteristics as the conductive layer. The data conductive layer may contain a metal or metal alloy such as aluminum (Al), copper (Cu), molybdenum (Mo), and titanium (Ti), and may be made of a single layer or multiple layers.

A passivation layer 181 and a via layer 182 may be sequentially formed on the data conductive layer and the interlayer insulating layer 161. For example, the passivation layer 181 may be formed of an inorganic insulating layer and may include one of silicon oxide SiOₓ, silicon nitride SiNₓ, and silicon oxynitride SiONₓ, or may be formed as a multiple-layer structure using these. The passivation layer 181 may have an inorganic insulating layer structure formed thicker than other inorganic insulating layers. The via layer 182 may be formed of an organic insulating layer and may include one or more materials selected from the group consisting of photoresist, polyacrylic resin, polyimide resin, acrylic resin, benzocyclobutene, and phenol resin. The via layer 182 may also be formed as a multiple layer.

An anode layer including an anode electrode Anode and a connection electrode CE may be positioned on the via layer 182. The anode electrode Anode may be electrically connected to the second region of the semiconductor layer ACT, which serves as the second electrode of the transistor, through hole OP2 positioned in the via layer 182, the passivation layer 181, the interlayer insulating layer 161, and the gate insulating layer 141. As a result, the anode electrode Anode may receive the output of the transistor.

Referring to FIGS. 2 and 3, the connection electrode CE may be formed from the same material as the anode electrode and may be electrically connected to the auxiliary driving low-voltage line 174-1 through the second opening positioned in the via layer 182 and the third opening positioned in the passivation layer 181. As a result, the connection electrode CE may receive the driving low-voltage ELVSS. The anode layer may be made of a single layer containing a transparent conductive oxide layer or a metal material, or a multiple layer containing these. The transparent conductive oxide layer may include indium tin oxide ITO, poly-ITO, indium zinc oxide IZO, indium gallium zinc oxide IGZO, and indium tin zinc oxide ITZO. Metal materials may include silver (Ag), molybdenum (Mo), copper (Cu), gold (Au), and aluminum (Al).

Above the anode layer, a pixel defining layer 380 that includes an opening OP may be formed, and as shown in FIGS. 2 and 3, the pixel defining layer 380 may also include a first opening that exposes the connection electrode CE.

The opening (OP; hereinafter also referred to as the light emitting element opening) of the pixel defining layer 380, corresponding to the light emitting area and/or the light emitting layer EML, may expose a portion of the anode electrode Anode, and may have a tapered sidewall.

The light emitting layer EML may be positioned in the opening OP of the pixel defining layer 380, and the light emitting layer EML may also be positioned on the pixel defining layer 380.

A first functional layer FL1 may be positioned between the anode electrode Anode and the light emitting layer EML, and a second functional layer FL2 may be positioned on the light emitting layer EML. For example, the first functional layer FL1 may include a hole injection layer and/or a hole transport layer, and the second functional layer FL2 may include an electron transport layer and/or an electron injection layer. For example, the functional layer FL and the light emitting layer EML may be combined to form an intermediate layer EL. The first functional layer FL1 and the second functional layer FL2 are formed on the pixel defining layer 380 and in the opening OP. Therefore, in the embodiment of FIG. 19, both intermediate layers EL may be positioned above the pixel defining layer 380 and in the opening OP. However, according to an embodiment, the light emitting layer EML may be positioned only in the opening OP of the pixel defining layer 380, and the functional layer FL may be formed both above the pixel defining layer 380 and in the opening OP.

A cathode electrode Cathode may be formed on the second functional layer FL2, the pixel defining layer 380, and the opening OP.

An anode electrode Anode, a light emitting layer EML, and a cathode electrode Cathode may constitute a light emitting diode, and the light emitting diode may further include a functional layer FL.

The current transmitted to the anode electrode Anode may pass through the first functional layer FL1, the light emitting layer EML, and the second functional layer FL2 and may be transmitted to the cathode electrode Cathode. The light emitting layer EML may emit light due to the current flowing through the light emitting layer EML, and the light emitting diode may display luminance.

In other embodiments, a spacer may be further formed on the pixel defining layer 380, and the spacer may have a tapered sidewall like the pixel defining layer 380.

Although the structure on the cathode electrode Cathode is not shown in FIG. 19, the encapsulation layer may be positioned in other embodiments. The encapsulation layer may include at least one inorganic layer and at least one organic layer, and may have a triple-layer structure including a first inorganic encapsulation layer, an organic encapsulation layer, and a second inorganic encapsulation layer. The encapsulation layer may be used to protect the light emitting layer EML from moisture or oxygen that may enter from the outside. In other embodiments, the encapsulation layer may include a structure in which an inorganic layer and an organic layer are further sequentially stacked.

In other embodiments, a sensing insulating layer and a plurality of sensing electrodes may be positioned on the encapsulation layer for touch sensing.

In other embodiments, a film including a polarizing plate may be attached to the encapsulation layer to reduce reflection of external light. A color filter or color conversion layer may be further formed to improve color quality, in which case a polarizer may not be attached. A light blocking layer may be positioned between the color filter or the color conversion layer. In other embodiments, a layer formed with a material (hereinafter referred to as a reflection control material) capable of absorbing light of some wavelengths of external light may be further included, in which case a polarizer may not be attached. In other embodiments, the front surface of the light emitting display device may be flattened by covering it with an additional organic layer (also called a planarization layer).

FIG. 19 is a schematic cross-sectional structure according to one embodiment, but various modified structures may also be possible.

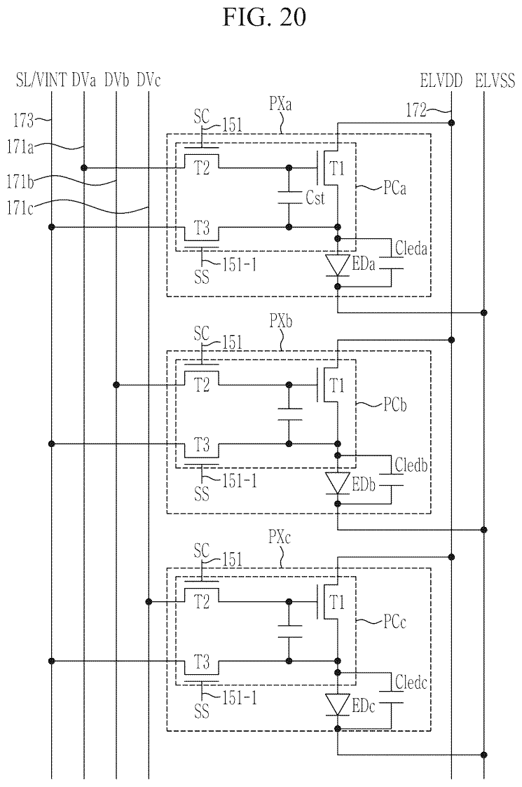

Hereinafter, the circuit structure of a pixel included in a light emitting display device according to an embodiment will be looked at with reference to FIG. 20.

FIG. 20 is a schematic diagram of an equivalent circuit of a pixel of a light emitting display device according to an embodiment.

FIG. 20 shows a circuit diagram of three pixels PXa, PXb, and PXc.

The plurality of pixels may include a first pixel PXa, a second pixel PXb, and a third pixel PXc. Each of the first pixel PXa, the second pixel PXb, and the third pixel PXc includes multiple transistors T1, T2, and T3, a storage capacitor Cst, and a light emitting diode EDa, EDb, and EDc. For example, a single pixel PXa, PXb, and PXc may be divided into a light emitting diode EDa, EDb, and EDc and a pixel driver PCa, PCb, and PCc, and the pixel driver PCa, PCb, and PCc may be formed on the driver element layer of FIG. 19. Referring to FIG. 20, the pixel drivers PCa, PCb, and PCc may include multiple transistors T1, T2, and T3 and a storage capacitor Cst corresponding to parts other than the light emitting diodes EDa, EDb, and EDc in each pixel PXa, PXb, and PXc.

In other embodiments, capacitors (Cleda, Cledb, and Cledc; hereinafter referred to as light emitting unit capacitors) electrically connected to both ends of the light emitting diodes EDa, EDb, and EDc may be further included, and a light emitting unit capacitor Cleda, Cledb, and Cledc may not be included in the pixel driver and may be included in the light emitting diodes EDa, EDb, and EDc.

Multiple transistors T1, T2, and T3 may include one driving transistor (T1; also called the first transistor) and two switching transistors T2 and T3, where the two switching transistors are distinguished as the input transistor (T2; also called the second transistor) and the reset transistor (T3; also called the third transistor). Each transistor T1, T2, and T3 may include a gate electrode, a first electrode, and a second electrode, and also may include a semiconductor layer including a channel so that current flows or blocks the channel of the semiconductor layer depending on the voltage of the gate electrode. For example, one of the first and second electrodes may be a source electrode and the other may be a drain electrode depending on the voltage applied to each transistor T1, T2, and T3.

The gate electrode of the driving transistor T1 may be electrically connected to one end of the storage capacitor Cst, and may be also electrically connected to the second electrode (output electrode) of the input transistor T2. The first electrode of the driving transistor T1 may be electrically connected to the driving voltage line 172 that delivers the driving voltage ELVDD, and the second electrode of the driving transistor T1 may be electrically connected to the anode electrode of the light emitting diodes EDa, EDb, and EDc, another end of the storage capacitor Cst, the first electrode of the initialization transistor T3, and one end of the light emitting unit capacitors Cleda, Cledb, and Cledc. The driving transistor T1 may receive the data voltage DVa, DVb, and DVc to the gate electrode according to the switching operation of the input transistor T2, and may supply the driving current to the light emitting diodes EDa, EDb, and EDc depending on the voltage of the gate electrode. The storage capacitor Cst may store and maintain the voltage of the gate electrode of the driving transistor T1.

The gate electrode of the input transistor T2 may be electrically connected to the first scan signal line 151 that transmits the first scan signal SC. The first electrode of the input transistor T2 may be electrically connected to the data lines 171a, 171b, and 171c that transmit the data voltages DVa, DVb, and DVc, and the second electrode of the input transistor T2 may be electrically connected to one end of the storage capacitor Cst and the gate electrode of the driving transistor T1. Multiple data lines 171a, 171b, and 171c respectively may transmit different data voltages DVa, DVb, and DVc, and the input transistor T2 of each pixel PXa, PXb, and PXc may transmit different data lines 171a, 171b, and 171c. The gate electrode of the input transistor T2 of each pixel PXa, PXb, and PXc may be electrically connected to the same first scan signal line 151 and may receive the first scan signal SC with the same timing. Even if the input transistors T2 of each pixel PXa, PXb, and PXc are simultaneously turned on by the first scan signal SC with the same timing, different data voltages DVa, DVb, and DVc may be transmitted to one end of the gate electrode of the driving transistor T1 and the storage capacitor Cst of each pixel PXa, PXb, and PXc through different data lines 171a, 171b, and 171c.

FIG. 20 is an embodiment in which the gate electrode of the initialization transistor T3 receives a different scan signal from the gate electrode of the input transistor T2.

The gate electrode of the initialization transistor T3 may be electrically connected to the second scan signal line 151-1 that transmits the second scan signal SS. The first electrode of the initialization transistor T3 may be electrically connected to another end of the storage capacitor Cst, the second electrode of the driving transistor T1, the anode electrodes Anode of the light emitting diodes EDa, EDb, and EDc, and one end of the light emitting unit capacitors Cleda, Cledb, and Cledc, and the second electrode of the initialization transistor T3 may be electrically connected to the initialization voltage line 173 that delivers the initialization voltage VINT. The initialization transistor T3 may be turned on according to the second scan signal SS and may deliver the initialization voltage VINT to one end of the anode electrode Anode of the light emitting diodes EDa, EDb, and EDc, the light emitting capacitors Cleda, Cledb, an Cledc, and another end of the storage capacitor Cst, thereby initializing the voltage of the anode electrode Anode of the light emitting diodes EDa, EDb, and EDc.

The initialization voltage line 173 may function as a sensing line SL by detecting the voltage of the anode electrode Anode of the light emitting diodes EDa, EDb, and EDc before applying the initialization voltage VINT. Through the sensing operation, it may be confirmed whether the voltage of the anode electrode is maintained at the target voltage. The detection operation and the initialization operation of transferring the initialization voltage VINT may be performed separately in time, and the initialization operation may be performed after the detection operation is performed.

In the embodiment of FIG. 20, the turn-on period of the initialization transistor T3 and the input transistor T2 may be distinguished so that the write operation performed by the input transistor T2 and the initialization operation performed by the initialization transistor T3 (and/or detection operation) may be performed at different timings.

One end of the storage capacitor Cst may be electrically connected to the gate electrode of the driving transistor T1 and the second electrode of the input transistor T2, and another end may be electrically connected to the first electrode of the initialization transistor T3, the second electrode of the driving transistor T1, the anode electrodes Anode of the light emitting diodes EDa, EDb, and EDc, and one end of the light emitting unit capacitors Cleda, Cledb, and Cledc.

The light emitting diodes EDa, EDb, and EDc may receive the output current from the driving transistor T1 at the anode electrode Anode, and the cathode electrodes Cathode of the light emitting diodes EDa, EDb, and EDc may receive the driving low-voltage ELVSS through the driving low-voltage line 174, and the light emitting diodes EDa, EDb, and EDc may emit light according to the output current of the driving transistor T1 to display gradation.

The light emitting capacitors Cleda, Cledb, and Cledc may be formed on both ends of the light emitting diodes EDa, EDb, and EDc so that the voltage across the light emitting diodes EDa, EDb, and EDc may be kept constant, whereby the light emitting diodes EDa, EDb, and EDc) display constant luminance.

Below, the operation of a pixel having the circuit shown in FIG. 20 will be examined.

In FIG. 20, each transistor T1, T2, and T3 may be an N-type transistor, and may have the characteristic of being turned on in case that a high-level voltage is applied to the gate electrode. However, in other embodiments, each transistor T1, T2, and T3 may be a P-type transistor.

One frame may begin in case that the emission section ends. Afterwards, the high-level of the second scan signal SS may be supplied to turn on the initialization transistor T3. In case that the initialization transistor T3 is turned on, an initialization operation and/or a detection operation may be performed.

The following will focus on an embodiment in which both the initialization operation and the detection operation are performed.

A detection operation may be performed before the initialization operation is performed. For example, in case that the initialization transistor T3 is turned on, the initialization voltage line 173 may function as a sensing line SL to detect the voltage of the anode electrode Anode of the light emitting diodes EDa, EDb, and EDc. Through the sensing operation, it may be confirmed whether or not the anode electrode voltage is maintained at the target voltage.

Afterward, an initialization action may be performed, and the voltage at another end of the storage capacitor Cst, the second electrode of the driving transistor T1, and the anode electrodes Anode of the light emitting diodes EDa, EDb, and EDc may be changed to the initialization voltage VINT transmitted from the initialization voltage line 173 to perform the initialization.

The detection operation and the initialization operation for transferring the initialization voltage VINT may be performed at a separate timing, allowing the pixel to perform various operations while using a minimum number of transistors and reducing the area occupied by the pixel. As a result, the resolution of the display panel may be improved.

Simultaneously with the initialization operation or at a separate timing, the first scan signal SC may be also applied as it changes to a high level so that the input transistor T2 is turned on, and a write operation may be performed. For example, the data voltages DVa, DVb, and DVc from the data lines 171a, 171b, and 171c may be input and may be stored at one end of the gate electrode of the driving transistor T1 and the storage capacitor Cst through the turned-on input transistor T2.

Through the initialization operation and the writing operation, data voltages DVa, DVb, and DVc and the initialization voltage VINT are applied to both ends of the storage capacitor Cst, respectively. In case that the initialization transistor T3 is turned on, even if the output current is generated in the driving transistor T1, it may be output to the outside through the initialization transistor T3 and the initialization voltage line 173 so that the light emitting diodes EDa, EDb, and EDc may not be input to the anode electrode Anode. According to the embodiment, during the writing period in case that a high-level of the first scan signal SC is supplied, it is possible to apply a driving voltage ELVDD at a low-level voltage or apply a driving low-voltage ELVSS at a high-level voltage to prevent current from flowing through the light emitting diodes EDa, EDb, and EDc.

Thereafter, in case that the first scan signal SC changes to a low level, the driving transistor T1 may generate and output an output current due to the high-level driving voltage ELVDD applied to the driving transistor T1 and the gate voltage of the driving transistor T1 stored in the storage capacitor Cst. The output current of the driving transistor T1 may be input to the light emitting diodes EDa, EDb, and EDc, and a light emission period may occur in which the light emitting diodes EDa, EDb, and EDe emit light.

On the other hand, according to the embodiment, more conductive layers may be used to form the light emitting display device differently from FIG. 18, and another embodiment having a different stacked structure is examined through FIG. 21 below.

FIG. 21 is a table schematically illustrating steps for manufacturing some layers of a light emitting display device according to another embodiment.

The light emitting display device according to FIG. 21, unlike FIG. 18, includes two conductive layers as data conductive layers (the first data conductive layer SD1 and the second data conductive layer SD2), and includes two passivation layers, the first passivation layer 181-1 and the second passivation layer 181-1, and also includes two via layers, the first via layer 182-1 and the second via layer 182-2.

The light emitting display device according to the embodiment of FIG. 21 has the same layered structure as that of FIG. 18 from the lower shielding layer BML to the interlayer insulating layer 161. In the embodiment of the light emitting display device of FIG. 21, the first data conductive layer SD1 is positioned above the interlayer insulating layer 161, and above the first data conductive layer SD1, the first passivation layer 181-1 and the first via layer 182-1 are sequentially positioned. The first via layer 182-1 is positioned above the second data conductive layer SD2, and the second passivation layer 181-2 and the second via layer 182-2 are sequentially positioned above the second data conductive layer SD2. An anode layer including an anode electrode Anode and a connection electrode CE is positioned on the second via layer 182-2. A pixel defining layer 380 including an opening is formed on the anode layer.

FIG. 21 also specifies the layers using masks, and shows a total of 12 masks being used up to the pixel defining layer 380. Thus, the first mask is used to form the lower shielding layer BML, the second mask is used to form the semiconductor layer ACT, the third mask is used to form the gate conductive layer (gate), the fourth mask is used to form contact openings in the interlayer insulating layer 161, gate insulating layer 141, and/or buffer layer 111, the fifth mask is used to form the first data conductive layer SD1, the sixth mask is used to form contact openings in the first passivation layer 181-1, the seventh mask is used to form contact openings in the first via layer 182-1, the eighth mask is used to form the second data conductive layer SD2, the ninth mask is used to form contact openings in the second passivation layer 181-2, the tenth mask is used to form contact openings in the second via layer 182-2, the eleventh mask is used to form the anode layer including the anode electrode Anode and the connection electrode CE, and the twelfth mask is used to form openings in the pixel defining layer 380. Through the twelfth mask, the pixel defining layer 380 may form an opening (see OP in FIG. 19) exposing the anode electrode Anode and the first opening OPpdl shown in FIG. 1.

Meanwhile, according to the embodiment, the embodiments of FIGS. 1 to 3, 5 to 8, 10, 16, and 17 may also be applied to light emitting display devices with different layered structures and cross-sectional structures from those in FIGS. 18 to 21.

Although the embodiments of the disclosure have been described in detail above, the scope of the disclosure is not limited thereto, and various modifications and improvements made by those skilled in the art using the basic concepts of the disclosure defined in the following claims are also possible.

What is claimed is:

1. A light emitting display device, comprising:
a substrate;
a voltage line positioned on the substrate and transmitting a constant voltage;
a passivation layer positioned on the voltage line;
a via layer positioned on the passivation layer;
a connection electrode positioned on the via layer;
a pixel defining layer positioned on the connection electrode; and
a cathode electrode positioned on the pixel defining layer, wherein:
the pixel defining layer has a first opening that overlaps the connection electrode in a plan view,
the via layer has a second opening that overlaps the connection electrode in a plan view,
the passivation layer has a third opening that overlaps the connection electrode in a plan view,
the cathode electrode and the connection electrode are electrically connected to each other through the first opening of the pixel defining layer,
the voltage line and the connection electrode are electrically connected to each other through the second opening of the via layer and the third opening of the passivation layer, and
at least a portion of the third opening of the passivation layer does not overlap the second opening of the via layer in a plan view.

2. The light emitting display device of claim 1, wherein:
the second opening of the via layer and the third opening of the passivation layer are positioned in the first opening of the pixel defining layer in a plan view.

3. The light emitting display device of claim 2, wherein:
the third opening of the passivation layer and the second opening of the via layer have a planar shape in a plan view.

4. The light emitting display device of claim 3, wherein:
the third opening of the passivation layer and the second opening of the via layer have a triangular, rectangular, hexagonal, octagonal, or any polygonal planar shape, or a planar shape with a polygonal shape cut out.

5. The light emitting display device of claim 2, wherein:
a direction in which a long side of the second opening of the via layer extends is different from the direction in which an upper side of the third opening of the passivation layer extends.

6. The light emitting display device of claim 5, wherein:
a direction in which a long side of the second opening of the via layer extends is perpendicular to the direction in which the upper side of the third opening of the passivation layer extends.

7. The light emitting display device of claim 2, wherein:
the second opening of the via layer is positioned in the third opening of the passivation layer in a plan view.

8. The light emitting display device of claim 7, wherein:
the third opening of the passivation layer is flush with the first opening of the pixel defining layer in a plan view.

9. The light emitting display device of claim 1, wherein:
the voltage line is electrically connected to a light emitting display device to which a low driving voltage is applied.

10. The light emitting display device of claim 1, further comprising:
an anode electrode positioned on the via layer; wherein
the pixel defining layer further includes a fourth opening that overlaps the anode electrode in a plan view, and
the anode electrode and the connection electrode are formed of a same material.

11. The light emitting display device of claim 10, further comprising:
an intermediate layer positioned on the anode electrode and the pixel defining layer,
wherein the intermediate layer is opened by laser drilling at a portion overlapping the connection electrode to electrically connect the cathode electrode to the connection electrode.

12. A light emitting display device, comprising:
a substrate;
a voltage line positioned on the substrate and transmitting a constant voltage;
a via layer positioned on the voltage line;
a connection electrode positioned on the via layer;
a pixel defining layer positioned on the connection electrode; and
a cathode electrode positioned on the pixel defining layer, wherein
the pixel defining layer has a first opening that overlaps the connection electrode in a plan view,
the via layer has a second opening that overlaps the connection electrode in a plan view,
the cathode electrode and the connection electrode are electrically connected to each other through the first opening of the pixel defining layer,
the voltage line and the connection electrode are electrically connected to each other through the second opening of the via layer, and
at least a portion of the second opening of the via layer does not overlap the first opening of the pixel defining layer in a plan view.

13. The light emitting display device of claim 12, further comprising:
a passivation layer positioned between the voltage line and the via layer, wherein:
the passivation layer has a third opening that overlaps the connection electrode in a plan view, and
at least a portion of the third opening of the passivation layer does not overlap the first opening of the pixel defining layer.

14. The light emitting display device of claim 13, wherein:
the second opening of the via layer is positioned in the third opening of the passivation layer in a plan view.

15. The light emitting display device of claim 13, further comprising:
an anode electrode positioned on the via layer, wherein:
the pixel defining layer further includes a fourth opening that overlaps the anode electrode in a plan view, and
the anode electrode and the connection electrode are formed of a same material.

16. The light emitting display device of claim 15, further comprising:
an intermediate layer positioned on the anode electrode and the pixel defining layer,
wherein the intermediate layer is opened by laser drilling at a portion overlapping the connection electrode to electrically connect the cathode electrode to the connection electrode.

17. A light emitting display device, comprising:
a substrate;
a voltage line positioned on the substrate and transmitting a constant voltage;
a via layer positioned on the voltage line;
a connection electrode positioned on the via layer;
a pixel defining layer positioned on the connection electrode; and
a cathode electrode positioned on the pixel defining layer, wherein:
the pixel defining layer has a first opening that overlaps the connection electrode in a plan view,
the via layer has a second opening that overlaps the connection electrode in a plan view,
the cathode electrode and the connection electrode are electrically connected to each other through the first opening of the pixel defining layer,
the voltage line and the connection electrode are electrically connected to each other through the second opening of the via layer, and
the second opening of the via layer has a planar shape in a plan view.

18. The light emitting display device of claim 17, wherein:
the second opening of the via layer has a triangular, rectangular, hexagonal, octagonal, or any polygonal planar shape, or a planar shape with a polygonal shape cut out.

19. The light emitting display device of claim 17, further comprising:
an anode electrode positioned on the via layer, wherein:
the pixel defining layer further includes an opening that overlaps the anode electrode in a plan view, and
the anode electrode and the connection electrode are formed of a same material.

20. The light emitting display device of claim 19, further comprising:
an intermediate layer positioned on the anode electrode and the pixel defining layer,
wherein the intermediate layer is opened by laser drilling at a portion overlapping the connection electrode to electrically connect the cathode electrode to the connection electrode.
